(19) United States
(12) Patent Application Publication
(10) Pub. No.: US 2026/0060060 A1
(43) Pub. Date: Feb. 26, 2026

(54) VARIABLE CELL HEIGHT INTEGRATION

(71) Applicant: QUALCOMM Incorporated, San Diego, CA (US)

(72) Inventors: Shreesh NARASIMHA, Charlotte, NC (US); Yan SUN, San Diego, CA (US); Raheel AZMAT, Cork (IE)

(21) Appl. No.: 18/809,857

(22) Filed: Aug. 20, 2024

(51) Int. Cl. H01L 23/528; H01L 27/092; H01L 29/06; H01L 29/423; H01L 29/66; H01L 29/775; H01L 29/78; H01L 29/786

(52) U.S. Cl. CPC H01L 23/5286; H01L 23/528; H10D 30/014; H10D 30/024; H10D 30/43; H10D 30/62; H10D 30/6735; H10D 30/6757; H10D 62/121; H10D 84/853

(57) ABSTRACT

A chip includes first backside rails, wherein each of the first backside rails extends in a first direction, and the first backside rails are spaced apart by a uniform pitch in a second direction perpendicular to the first direction. The chip also includes second backside rails, wherein each of the second backside rails extends in the first direction, and the second backside rails are spaced apart by a variable pitch in the second direction.

### BACKGROUND

### Field

Aspects of the present disclosure relate generally to chip layout, and more particularly, to placement of cells with variable heights.

### Background

A chip includes many transistors for performing various functions on the chip. The transistors may be implemented using fin field effect transistors (FinFETs), gate-all-around field effect transistors (GAAFETs), and/or other types of transistors. Transistors on the chip may be organized into cells. Each cell may include one or more transistors that are arranged to implement a circuit (e.g., an inverter, a driver, a logic gate, combinational logic, or another type of circuit). The chip may also include frontside metal layers and/or backside metal layers to provide power routing and signal routing for the cells.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes first backside rails, wherein each of the first backside rails extends in a first direction, and the first backside rails are spaced apart by a uniform pitch in a second direction perpendicular to the first direction. The chip also includes second backside rails, wherein each of the second backside rails extends in the first direction, and the second backside rails are spaced apart by a variable pitch in the second direction.

A second aspect relates to a chip. The chip includes first backside rails extending in a first direction, and first cells within a first area of the chip, wherein the first cells have a uniform height in a second direction perpendicular to the first direction, and the first backside rails extend under the first cells. The chip also includes second backside rails extending in the first direction, and second cells within a second area of the chip, wherein the second cells have a variable height in the second direction, and the second backside rails extend under the second cells.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a gate-all-around FET according to certain aspects of the present disclosure.

FIG. 1C shows a perspective view of the transistor implemented with a FinFET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2A shows a top view of an exemplary layout of diffusion regions and gates in a cell according to certain aspects of the present disclosure.

FIG. 2B shows an example in which the orientation of the diffusion regions in FIG. 2A is flipped in the y direction according to certain aspects of the present disclosure.

FIG. 3A shows a top view of an exemplary layout of an n-well and a p-well in the cell according to certain aspects of the present disclosure.

FIG. 3B shows an example in which the orientation of the n-well and the p-well in FIG. 3A is flipped in the y direction according to certain aspects of the present disclosure.

FIG. 4A shows a top view of an exemplary layout of a positive supply rail and a ground rail for routing power to the cell according to certain aspects of the present disclosure.

FIG. 4B shows an example in which the orientation of the positive supply rail and the ground rail in FIG. 4A is flipped in the y direction according to certain aspects of the present disclosure.

FIG. 5A shows an exemplary layout of cells arranged in rows according to certain aspects of the present disclosure.

FIG. 5B shows an exemplary layout of positive supply rails and ground rails arranged along boundaries of the rows of FIG. 5A according to certain aspects of the present disclosure.

FIG. 5C shows an exemplary layout of diffusion regions in the rows of FIG. 5A according to certain aspects of the present disclosure.

FIG. 5D shows an exemplary layout of n-wells and p-wells in the rows of FIG. 5A according to certain aspects of the present disclosure.

FIG. 6 shows a top view of a cell that receives power using backside power routing according to certain aspects of the present disclosure.

FIG. 7A shows a top view of an example of a backside positive supply rail and a backside ground rail extending under the cell of FIG. 6 according to certain aspects of the present disclosure.

FIG. 7B shows a cross-sectional view of the cell of FIG. 6 and the backside positive supply rail and the backside ground rail of FIG. 7A according to certain aspects of the present disclosure.

FIG. 8 shows a top view of an exemplary layout of backside power routing according to certain aspects of the present disclosure.

FIG. 9A shows a top view of another example of a backside positive supply rail and a backside ground rail extending under the cell of FIG. 6 according to certain aspects of the present disclosure.

FIG. 9B shows a cross-sectional view of the cell of FIG. 6 and the backside positive supply rail and the backside ground rail of FIG. 9A according to certain aspects of the present disclosure.

FIG. 10 shows a top view of another exemplary layout of backside power routing according to certain aspects of the present disclosure.

FIG. 11 shows a top view of an exemplary layout of frontside signal routing according to certain aspects of the present disclosure.

FIG. 12A shows a top view of an example of cells having various heights in the y direction according to certain aspects of the present disclosure.

FIG. 12B shows a top view of another example of cells having various heights in the y direction according to certain aspects of the present disclosure.

FIG. 13 shows an example of a layout including a variable-cell-height area according to certain aspects of the present disclosure.

FIG. 14 shows an example of tracks extending over the variable-cell-height area to provide frontside signal routing according to certain aspects of the present disclosure.

FIG. 15A shows an example of backside rails extending under the variable-cell-height area to provide backside power routing according to certain aspects of the present disclosure.

FIG. 15B shows an example of a backside positive supply path and a backside ground path coupled to the backside rails of FIG. 15A according to certain aspects of the present disclosure.

FIG. 16 shows an example of cells in the variable-cell-height area according to certain aspects of the present disclosure.

FIG. 17 shows an example in which the variable-cell-height area includes rows with multiple cells in each row according to certain aspects of the present disclosure.

FIG. 18 shows another example of a layout including a variable-cell-height area according to certain aspects of the present disclosure.

FIG. 19 shows an example of tracks extending over the variable-cell-height area of FIG. 18 to provide frontside signal routing according to certain aspects of the present disclosure.

FIG. 20A shows an example of backside rails extending under the variable-cell-height area of FIG. 18 to provide backside power routing according to certain aspects of the present disclosure.

FIG. 20B shows an example of a backside positive supply path and a backside ground path coupled to the backside rails of FIG. 20A according to certain aspects of the present disclosure.

FIG. 21 shows an example of cells in the variable-cell-height area of FIG. 18 according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

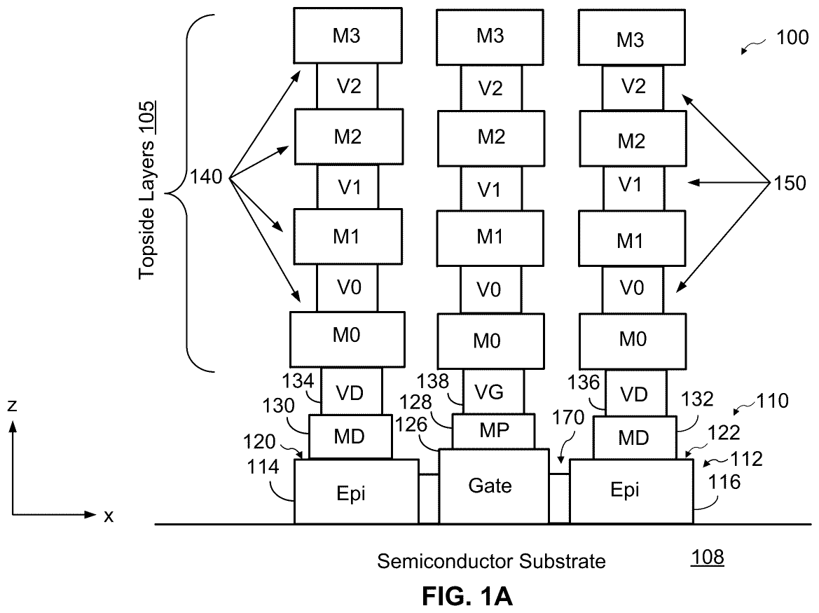

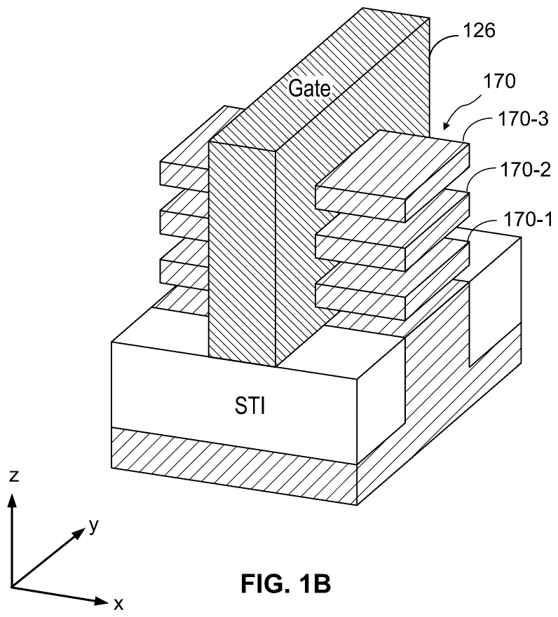

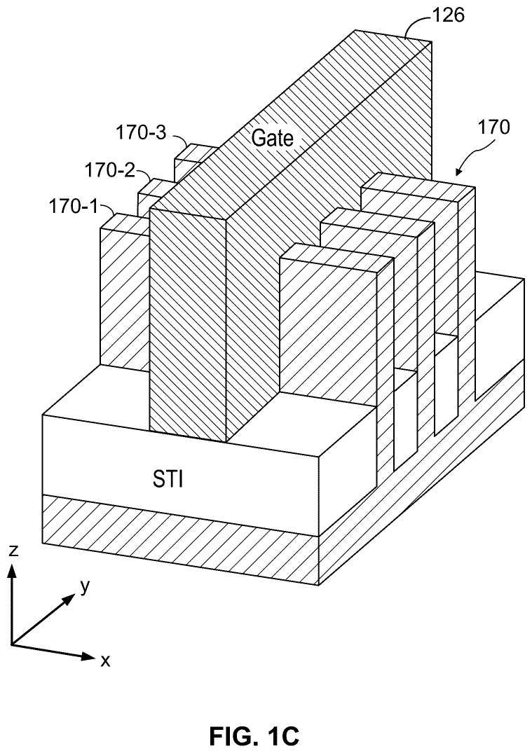

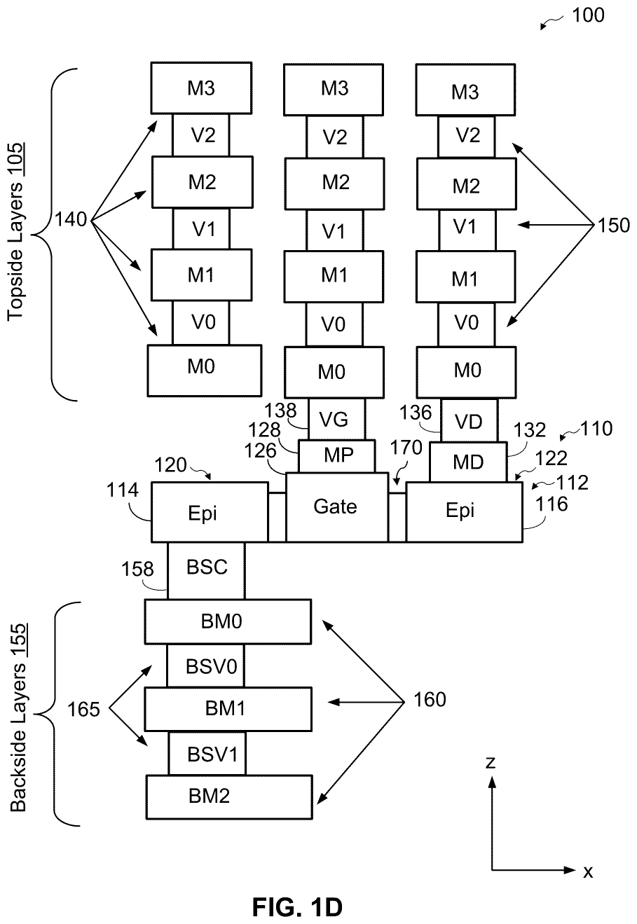

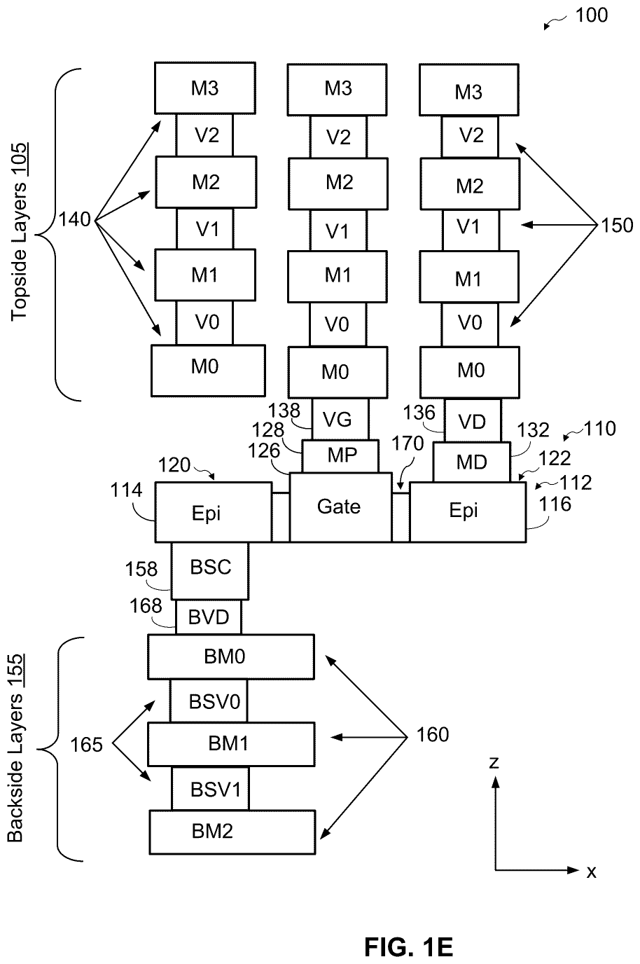

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor.

For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epi layers may be coupled to opposite sides of the one or more channels 170, as discussed further below.

For the example of a gate-all-around FET process, the gate 126 may surround each of the one or more channels 170 (also referred as ribbons) on four sides. In this regard, FIG. 1B shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example. In some implementations, the chip 100 may include shallow trench isolation (STI) to reduce leakage between devices on the chip 100. In other implementations, the STI may be omitted.

For the example of a FinFET process, the gate 126 may surround each of the one or more channels 170 on three sides. In this regard, FIG. 1C shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins. In some implementations, the chip 100 may include shallow trench isolation (STI) to reduce leakage between devices on the chip 100. In other implementations, the STI may be omitted.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a thin spacer (not shown in FIG. 1A) between the gate 126 and the first epi layer 114, and a thin spacer (not shown in FIG. 1A) between the gate 126 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including positive supply rails for distributing power to the transistor 110 and other transistors integrated on the chip 100. A positive supply rail may also be referred to as a power rail, a supply rail, Vdd rail, or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for ease of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V2. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 138 disposed between the gate contact 128 and metal layer M0, in which the via 138 couples the gate contact 128 (and hence the gate 126) to metal layer M0. For implementations where the gate contact 128 is omitted, the via 138 may be disposed between the gate 126 and metal layer M0 without an intervening gate contact. In this example, the chip 100 also includes a via 134 disposed between the contact 130 and metal layer M0, in which the via 134 couples the contact 130 to metal layer M0. The chip 100 also includes a via 136 disposed between the contact 132 and metal layer M0, in which the via 136 couples the contact 132 to metal layer M0.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP), backside etching, or any combination thereof). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include positive supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for ease of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including positive supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing. In general, the present disclosure is not limited to a particular allocation of power routing and signal routing between the topside layers 105 and the backside layers 155.

Although one gate 126 is shown in FIGS. 1A to 1E, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to implement a circuit (e.g., an inverter, a driver, a logic gate, combinational logic, a latch, a flip-flop, a bit cell, or another type of circuit). The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell. A cell that is defined in a standard cell library may also be referred to as a standard cell.

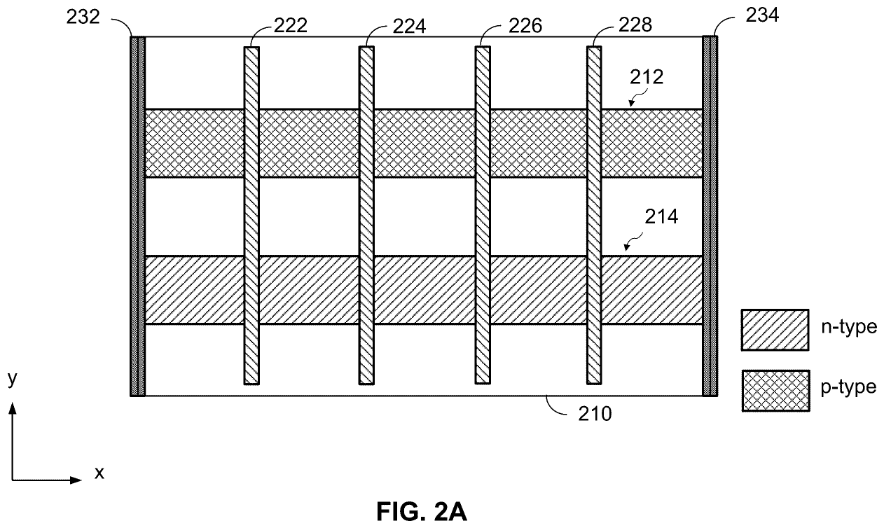

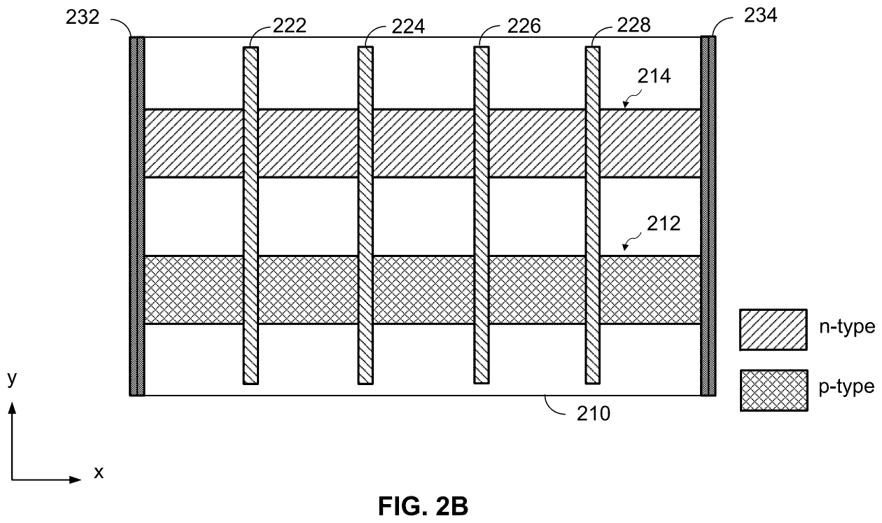

FIG. 2A shows a top view of an exemplary layout of a cell 210 (e.g., a standard cell) according to certain aspects of the present disclosure. In this example, the boundary of the cell 210 is indicated by the rectangular box shown in FIG. 2A.

In this example, the cell 210 include a p-type diffusion region 212 and a n-type diffusion region 214 extending in the x direction. It is to be appreciated that the cell 210 is not limited to two diffusion regions. In general, the cell 210 may include three or more diffusion regions spaced apart in the y direction. For example, in some implementations, the cell 210 may include two p-type diffusion regions and two n-type diffusion regions, as discussed further below.

In this example, the cell 210 also includes gates 222, 224, 226, and 228 extending in the y direction. The gates 222, 224, 226, and 228 may be spaced apart in the x direction by a uniform pitch, as shown in the example in FIG. 2A. Each of the gates 222, 224, 226, and 228 may include a metal (e.g., a high-k metal gate (HKMG)), polysilicon, and/or another gate material. It is to be appreciated that the cell 210 is not limited to the number of gates shown in the example in FIG. 2A, and that the cell 210 may include a smaller number of gates or a larger number of gates (e.g., depending on the complexity of the circuit implemented by the cell 210). It is also to be appreciated that one or more of the gates 222, 224, 226, and 228 may be cut between the p-type diffusion region 212 and the n-type diffusion region 214 (depending on the circuit implemented by the cell 210).

In this example, the p-type diffusion region 212 may include one or more channels (e.g., the one or more channels 170) passing through the gates 222, 224, 226, and 228 and epi layers (e.g., the epi layers 114 and 116) between the gates 222, 224, 226, and 228. The p-type diffusion region 212 and the gates 222, 224, 226, and 228 may form one or more p-type field effect transistors (PFETs) in the cell 210. The n-type diffusion region 214 may include one or more channels (e.g., the one or more channels 170) passing through the gates 222, 224, 226, and 228 and epi layers (e.g., the epi layers 114 and 116) between the gates 222, 224, 226, and 228. The n-type diffusion region 214 and the gates 222, 224, 226, and 228 may form one or more n-type field effect transistors (NFETs) in the cell 210.

FIG. 2A also shows an example of a first diffusion break 232 on the left boundary of the cell 210, and a second diffusion break 234 on the right boundary of the cell 210. The diffusion breaks 232 and 234 may be used to isolate the diffusion regions 212 and 214 from diffusion regions of adjacent cells (not shown in FIG. 2A). Each of the diffusion breaks 232 and 234 may include a single diffusion break, a double diffusion break, or another type of diffusion break.

FIG. 2B shows an example of the cell 210 in which the orientation of the p-type diffusion region 212 and the n-type diffusion region 214 is flipped in the y direction with respect to the orientation of the p-type diffusion region 212 and the n-type diffusion region 214 in FIG. 2A.

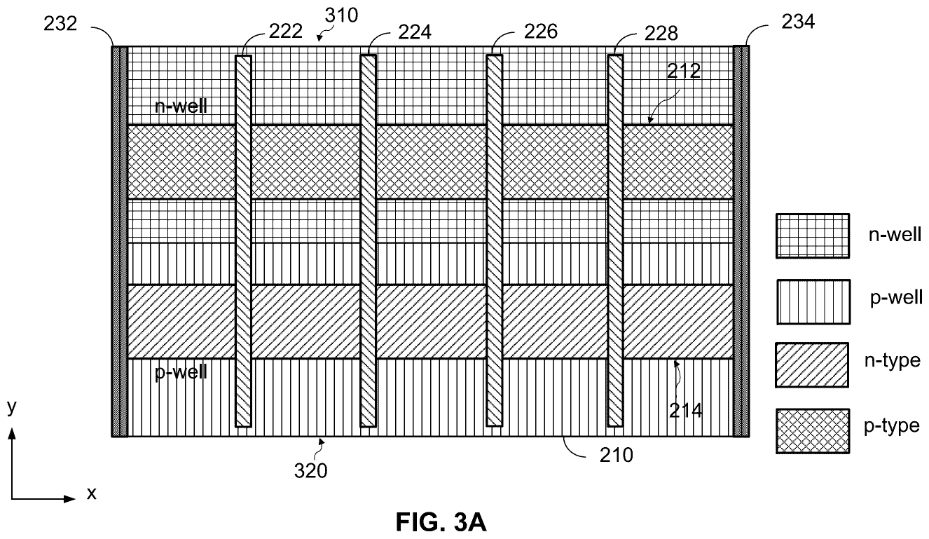

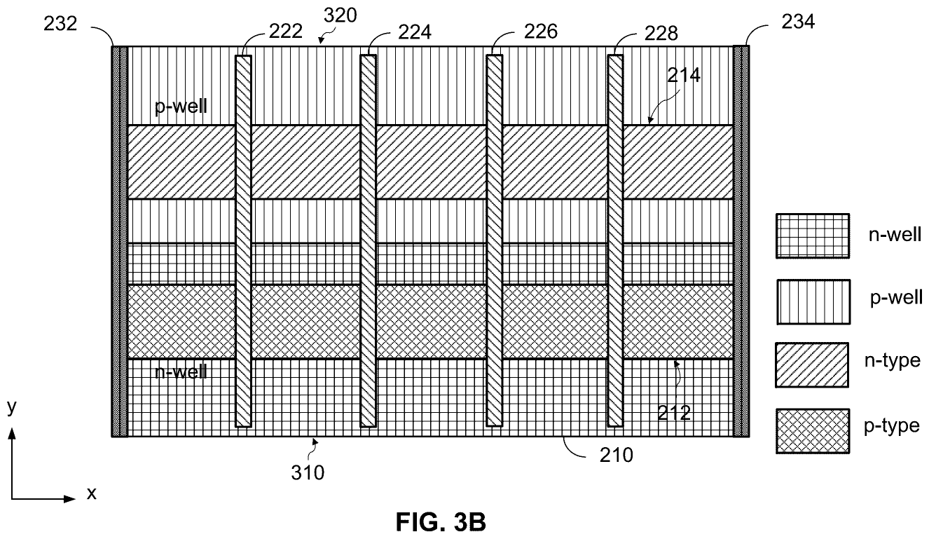

In certain aspects, the cell 210 is formed on the semiconductor substrate 108 (shown in FIG. 1A). In this regard, FIG. 3A shows an example in which an n-well 310 is formed in the substrate 108 to provide a substrate region for the PFET(s) and a p-well 320 is formed in the substrate 108 to provide a substrate region for the NFET(s). In the example in FIG. 3A, the n-well 310 extends in the x direction under the p-type diffusion region 212, and the p-well 320 extends in the x direction under the n-type diffusion region 214. In this example, the n-well 310 may be coupled to a supply voltage by an n-well tap cell (not shown) and the p-well 320 may be coupled to ground potential by a p-well tap cell (not shown). In certain aspects, n-well tap cells and p-well tap cells may be placed periodically on the chip 100 to tie n-wells to the supply voltage and tie p-wells to ground potential to prevent latch up. As discussed further below, the n-well 310 and the p-well 320 may be omitted in some implementations (e.g., implementations where all or substantially all of the substrate 108 is removed to form the backside layers 155 shown in FIGS. 1D and 1E). For example, the n-well 310 and the p-well 320 may be omitted for a substrate-free implementation with a backside power distribution network (BSPDN).

FIG. 3B shows an example in which the orientation of the n-well 310 and the p-well 320 is flipped in the y direction with respect to the orientation of the n-well 310 and the p-well 320 in FIG. 3A. In this example, the orientation of the p-type diffusion region 212 and the n-type diffusion region 214 is also flipped in the y direction with respect to the orientation of the p-type diffusion region 212 and the n-type diffusion region 214 in FIG. 3A.

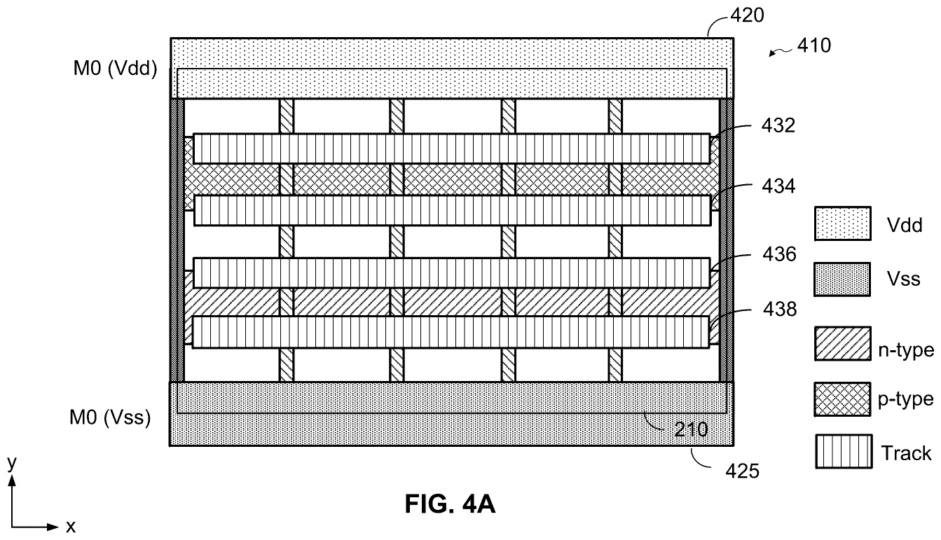

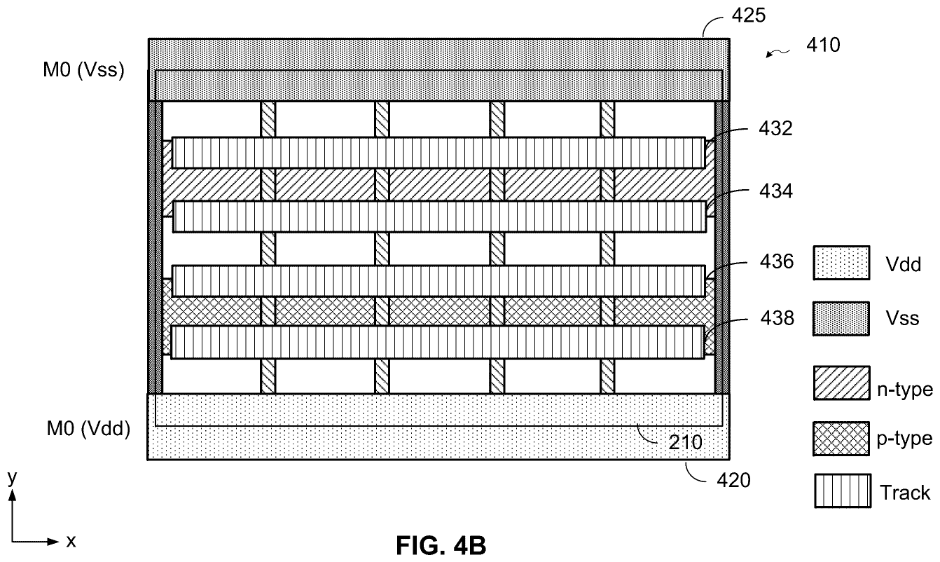

FIG. 4A shows a top view of an exemplary layout 410 for power routing and signal routing in metal layer M0 over the cell 210. FIG. 4A shows an example of frontside power routing in which power is routed to the cell 210 from the frontside (e.g., using a power distribution network formed in the topside metal layers 105 in FIG. 1A).

In the example in FIG. 4A, the layout 410 includes a positive supply rail 420 and a ground rail 425 that provide frontside power routing for the cell 210. Each of the rails 420 and 425 is elongated and extends in the x direction. Each of the rails 420 and 425 are formed in metal layer M0 (e.g., using lithography and etching processes). Although the positive supply rail 420 and the ground rail 425 are formed in the same metal layer, the positive supply rail 420 and the ground rail 425 are shown with different shading in FIG. 4A to visually distinguish the positive supply rail 420 and the ground rail 425. As discussed above, a positive supply rail may also be referred to as a Vdd rail. A ground rail may also be referred to as a negative supply rail, a Vss rail, or another term.

In the example shown in FIG. 4A, the positive supply rail 420 overlaps the top boundary (i.e., edge) of the cell 210 in the x and y directions, and the ground rail 425 overlaps the bottom boundary (i.e., edge) of the cell 210 in the x and y directions. The p-type diffusion region 212 may be coupled to the positive supply rail 420 through one or more contacts (e.g., MD contact in FIG. 1A) and one or more vias (e.g., VD via in FIG. 1A). The n-type diffusion region 214 may be coupled to the ground rail 425 through one or more contacts (e.g., MD contact in FIG. 1A) and one or more vias (e.g., VD via in FIG. 1A). As discussed further below, the cell 210 may share the positive supply rail 420 and the ground rail 425 with one or more other cells on the chip 100.

In the example shown in FIG. 4A, the layout 410 also includes tracks 432, 434, 436, and 438 in metal layer M0 located between the positive supply rail 420 and the ground rail 425 in the y direction. The tracks 432, 434, 436, and 438 are used to provide signal routing for the cell 210. Each of the tracks 432, 434, 436, and 438 is elongated and extends in the x direction. The tracks 432, 434, 436, and 438 are spaced apart in the y direction (e.g., by a uniform pitch). A track may also be referred to as a wire or another term. Each of the tracks 432, 434, 436, and 438 may be coupled to one or more of the gates (e.g., through one or more MP contacts and one or more VG vias in FIG. 1A) and/or coupled to one or more of the diffusion regions 212 and 214 (e.g., through one or more MD contacts and one or more VD vias in FIG. 1A). The cell 210 may utilize all four tracks 432, 434, 436, and 438 for signal routing or less than all four tracks 432, 434, 436, and 438 for signal routing depending, for example, on the number of inputs and outputs of the circuit implemented by the cell 210. Although the tracks 432, 434, 436, and 438, the positive supply rail 420, the ground rail 425 are formed in the same metal layer (i.e., metal layer M0 in this example), the tracks 432, 434, 436, and 438 are shown with a different shading than the positive supply rail 420 and the ground rail 425 in FIG. 4A to visually distinguish the tracks 432, 434, 436, and 438 from the positive supply rail 420 and the ground rail 425.

For the example where the cell 210 includes the n-well 310 (shown in FIG. 3A), the n-well 310 may be coupled to the positive supply rail 420 through an n-well tap (not shown). The n-well tap may be located in another cell (not shown) in which the n-well 310 extends in the x direction to the other cell. For the example where the cell 210 includes the p-well 320 (shown in FIG. 3A), the p-well 320 may be coupled to the ground rail 425 through a p-well tap (not shown). The p-well tap may be located in another cell (not shown) in which the p-well 320 extends in the x direction to the other cell.

FIG. 4B shows an example in which the orientation of the positive supply rail 420 and the ground rail 425 is flipped in the y direction with respect to the orientation of the positive supply rail 420 and the ground rail 425 in FIG. 4A. In this example, the ground rail 425 overlaps the top boundary of the cell 210 in the x and y directions, and the positive supply rail 420 overlaps the bottom boundary of the cell 210 in the x and y directions. Also, in the example in FIG. 4B, the orientation of the p-type diffusion region 212 and the n-type diffusion region 214 is flipped in the y direction with respect to the orientation of the p-type diffusion region 212 and the n-type diffusion region 214 in FIG. 4A.

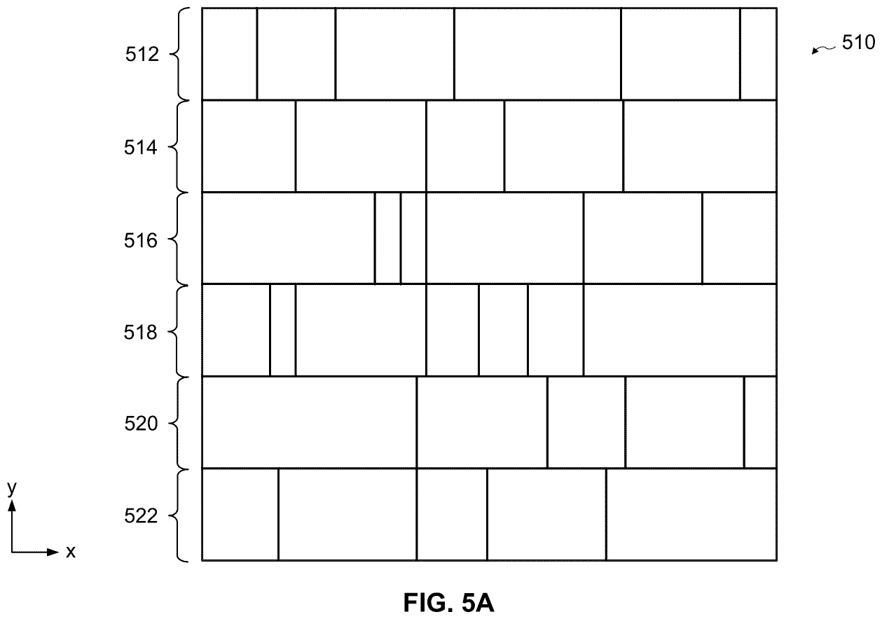

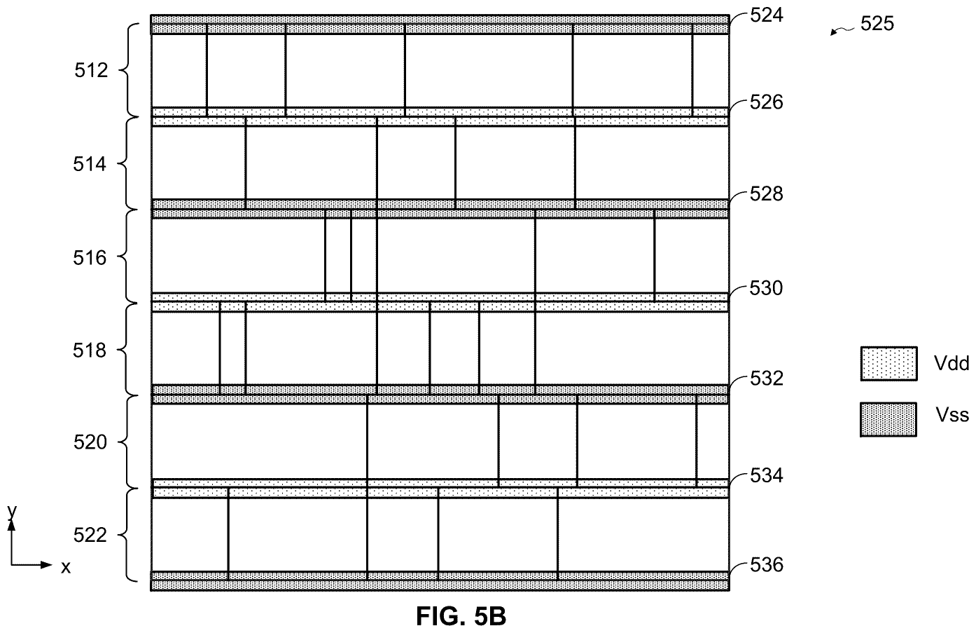

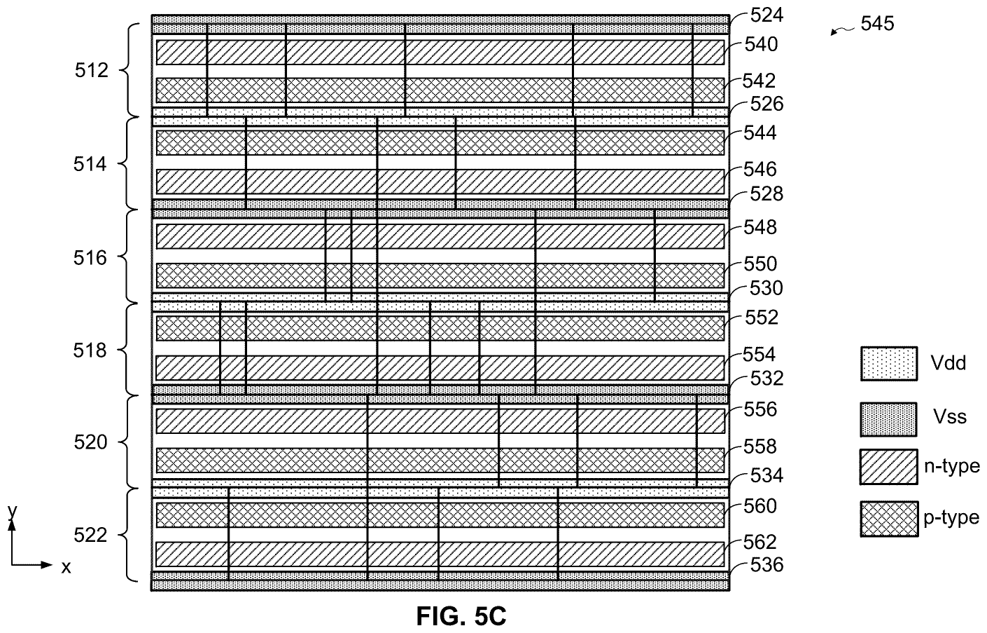

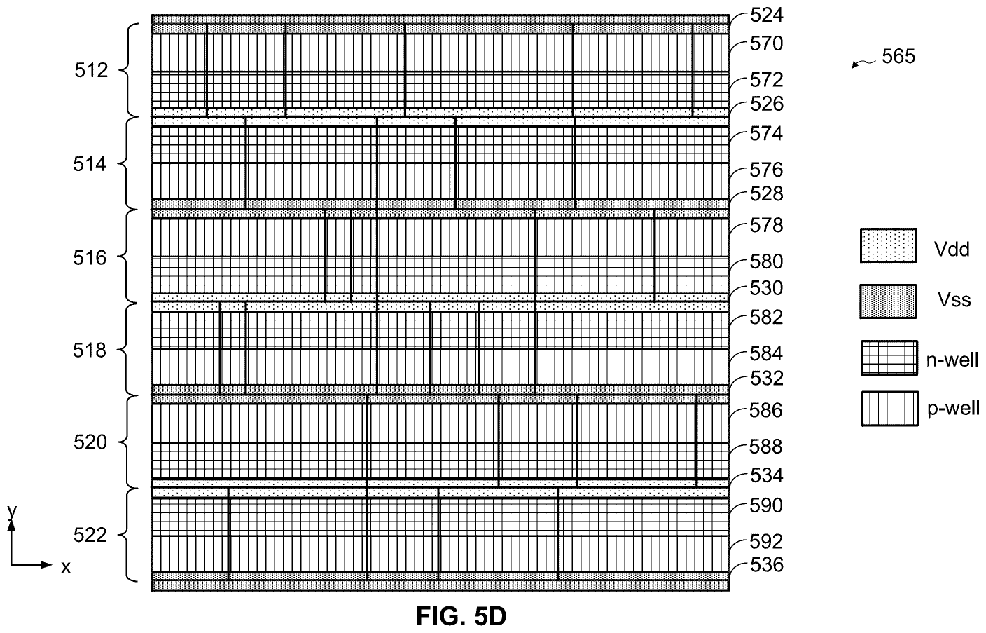

In certain aspects, standard cells may be arranged (i.e., laid out) in rows on the chip 100. In this regard, FIG. 5A shows a top view of an exemplary layout 510 of standard cells arranged in rows 512, 514, 516, 518, 520, and 522 extending in the x direction. In FIG. 5A, each cell is shown as a rectangular box delineating the boundary of the cell.

In this example, the cells in each of the rows 512, 514, 516, 518, 520, and 522 have the same height in the y direction. The cells in each of the rows 512, 514, 516, 518, 520, and 522 may have the same width in the x direction or varying widths in the x direction (e.g., based on the number of gates in each cell). For example, a cell with a larger number of gates may be wider in the x direction than a cell with a smaller number of gates.

FIG. 5B shows an example layout 525 of positive supply rails 526, 530, and 534 and ground rails 524, 528, 532, and 536 for distributing power to the cells in the rows 512, 514, 516, 518, 520, and 522. In this example, each of the positive supply rails 526, 530, and 534 extends in the x direction and each of the ground rails 524, 528, 532, and 536 extends in the x direction. Also, in this example, the layout 525 alternates between the positive supply rails 526, 530, and 534 and the ground rails 524, 528, 532, and 536 in the y direction. As discussed further below, the alternating arrangement of the positive supply rails 526, 530, and 534 and the ground rails 524, 528, 532, and 536 in the y direction allows each of the positive supply rails 526, 530, and 534 to be shared by cells in adjacent rows and each of the ground rails 524, 528, 532, and 536 to be shared by cells in adjacent rows.

In the example shown in FIG. 5B, each of the rows 512, 514, 516, 518, 520, and 522 is located between one of the positive supply rails 526, 530, and 534 and one of the ground rails 524, 528, 532, and 536. For example, the row 512 is located between the positive supply rail 526 and the ground rail 524. In this example, power is distributed to the cells in the row 512 using the positive supply rail 526 and the ground rail 524.

It is to be appreciated that the layout 525 may also include multiple tracks (not shown) within each of the rows 512, 514, 516, 518, 520, and 522 to provide signal routing for the cells in each of the rows 512, 514, 516, 518, 520, and 522. The tracks for each row may be formed in metal layer M0 and extend in the x direction. Also, the tracks in each row may be cut between the cells in the row to provide separate inputs and outputs for the cells.

FIG. 5C shows an example layout 545 of n-type diffusion regions 540, 546, 548, 554, 556, and 562 and p-type diffusion regions 542, 544, 550, 552, 558, and 560 according to certain aspects. Each of the n-type diffusion regions 540, 546, 548, 554, 556, and 562 and each of the p-type diffusion regions 542, 544, 550, 552, 558, and 560 extends in the x direction. In this example, each of the rows 512, 514, 516, 518, 520, and 522 includes a respective one of the n-type diffusion regions 540, 546, 548, 554, 556, and 562 and a respective one of the p-type diffusion regions 542, 544, 550, 552, 558, and 560. The layout 545 may also include diffusion breaks (not shown) on the boundaries of adjacent cells in the same row.

In the example in FIG. 5C, the orientation of the n-type diffusion region and the p-type diffusion region in each row is flipped in the y direction with respect to the orientation of n-type diffusion region and the p-type diffusion region in an adjacent row. For example, in FIG. 5C, the orientation of the n-type diffusion region 540 and the p-type diffusion region 542 in the row 512 is flipped in the y direction with respect to the orientation of the n-type diffusion region 546 and the p-type diffusion region 544 in the adjacent row 514. This places both the p-type diffusion region 542 in the row 512 and the p-type diffusion region 544 in the adjacent row 514 next to the positive supply rail 526 allowing the positive supply rail 526 to be shared by the cells in the rows 512 and 514.

Also, in FIG. 5C, the orientation of the n-type diffusion region 546 and the p-type diffusion region 544 in the row 514 is flipped in the y direction with respect to the orientation of the n-type diffusion region 548 and the p-type diffusion region 550 in the adjacent row 516. This places both the n-type diffusion region 546 in the row 514 and the n-type diffusion region 548 in the adjacent row 516 next to the ground rail 528 allowing the ground rail 528 to be shared by the cells in the rows 514 and 516.

FIG. 5D shows an example layout 565 of n-wells 572, 574, 580, 582, 588, and 590 and p-wells 570, 576, 578, 584, 586, and 592 according to certain aspects. Note that the n-type diffusion regions 540, 546, 548, 554, 556, and 562 and the p-type diffusion regions 542, 544, 550, 552, 558, and 560 are not shown in FIG. 5D in order to better show the n-wells 572, 574, 580, 582, 588, and 590 and the p-wells 570, 576, 578, 584, 586, and 592.

Each of the n-wells 572, 574, 580, 582, 588, and 590 and each of the p-wells 570, 576, 578, 584, 586, and 592 extends in the x direction. In this example, each of the rows 512, 514, 516, 518, 520, and 522 includes a respective one of the n-wells 572, 574, 580, 582, 588, and 590 and a respective one of the p-wells 570, 576, 578, 584, 586, and 592. In each of the rows 512, 514, 516, 518, 520, and 522, the respective one of the n-wells 572, 574, 580, 582, 588, and 590 is located under the respective one of the p-type diffusion regions 542, 544, 550, 552, 558, and 560 (shown in FIG. 5C). Also, in each of the rows 512, 514, 516, 518, 520, and 522, the respective one of the p-wells 570, 576, 578, 584, 586, and 592 is located under the respective one of the n-type diffusion regions 540, 546, 548, 554, 556, and 562 (shown in FIG. 5C). In certain aspects, adjacent n-wells and adjacent p-wells may be merged (e.g., the area of adjacent wells may be defined by one shape in a well implant mask used to form the wells). For example, the n-wells 572 and 574 may be merged, the p-wells 576 and 578 may be merged, the n-wells 580 and 582 may be merged, the p-wells 584 and 586 may be merged, and the n-wells 588 and 590 may be merged.

In the examples shown in FIGS. 5A to 5D, the cell 210 (which has a height of one row) may be freely placed in any one of the rows 512, 514, 516, 518, 520, and 522. This is because, the orientation of the p-type diffusion region 212 and the n-type diffusion region 214 in the cell 210 may be selected based on the row in which the cell is placed. For example, to place the cell 210 in the row 514, the exemplary orientation of the p-type diffusion region 212 and the n-type diffusion region 214 shown in FIG. 2A may be used. To place the cell 210 in the row 516, the exemplary orientation of the p-type diffusion region 212 and the n-type diffusion region 214 shown in FIG. 2B may be used. Thus, the cell 210 may use either one of the orientations of the p-type diffusion region 212 and the n-type diffusion region 214 shown in FIGS. 2A and 2B depending on the row in which the cell 210 is placed.

In the example FIG. 5D, the layout 565 of the n-wells 572, 574, 580, 582, 588, and 590 and the p-wells 570, 576, 578, 584, 586, and 592 place restrictions on the placement of cells. This is because a p-type diffusion region of a cell needs to be placed over one of the n-wells 572, 574, 580, 582, 588, and 590 and an n-type diffusion region of a cell needs to be placed over one of the p-wells 570, 576, 578, 584, 586, and 592 in the layout 565. The cell placement restrictions due to the n-wells 572, 574, 580, 582, 588, and 590 and the p-wells 570, 576, 578, 584, 586, and 592 may be eliminated using backside power routing for the cells. This is because all or substantially all of the substrate 108 is removed for backside processing which may eliminate the need for n-wells and p-wells, as discussed further below.

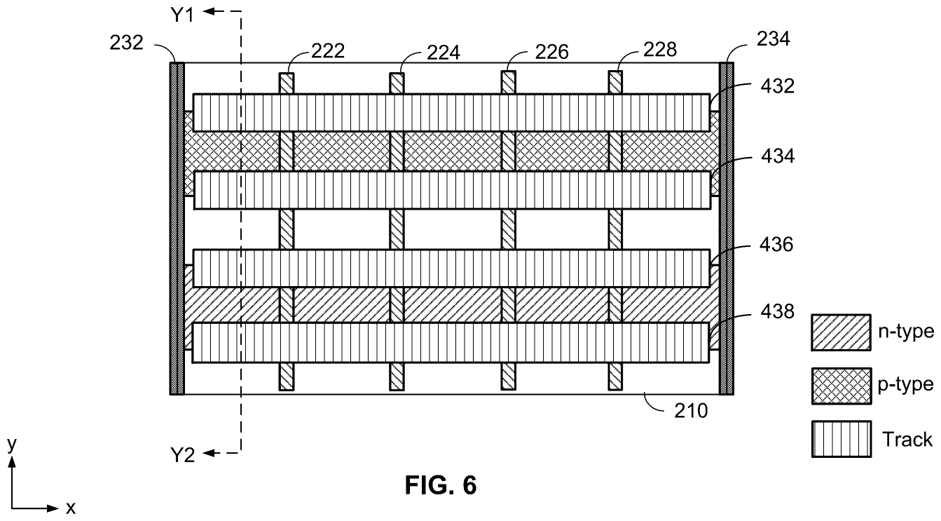

FIG. 6 shows a frontside top view of the cell 210 and the tracks 432, 434, 436, and 438 in metal layer M0. As discussed above, the tracks 432, 434, 436, and 438 provide signal routing for the cell 210. In this example, power is routed to the cell 210 from the backside using a backside power distribution network (BSPDN). Since power is routed from the backside in this example, the positive supply rail 420 and the ground rail 425 in metal layer M0 shown in FIGS. 4A and 4B are omitted. Moving the power routing to the backside reduces signal routing congestion by freeing up more space in the topside layers 105 for signal routing.

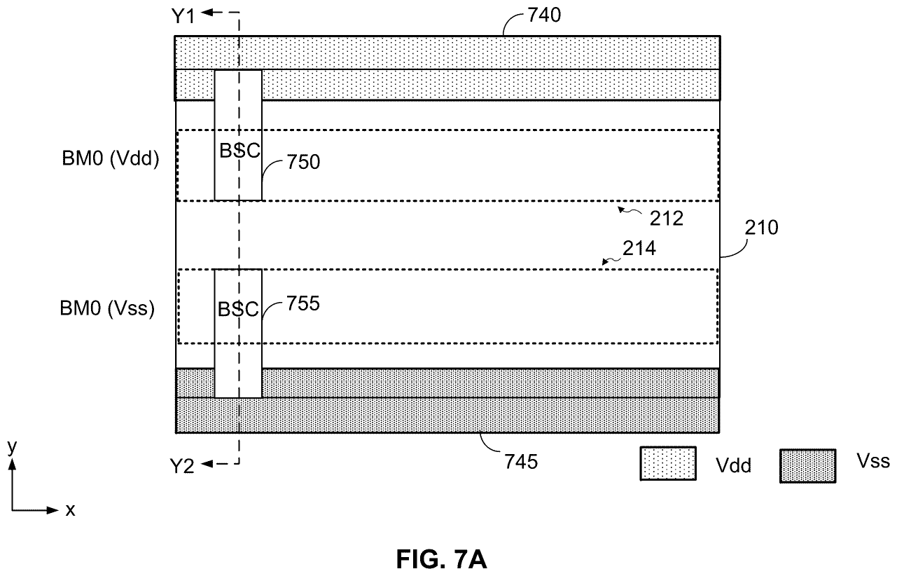

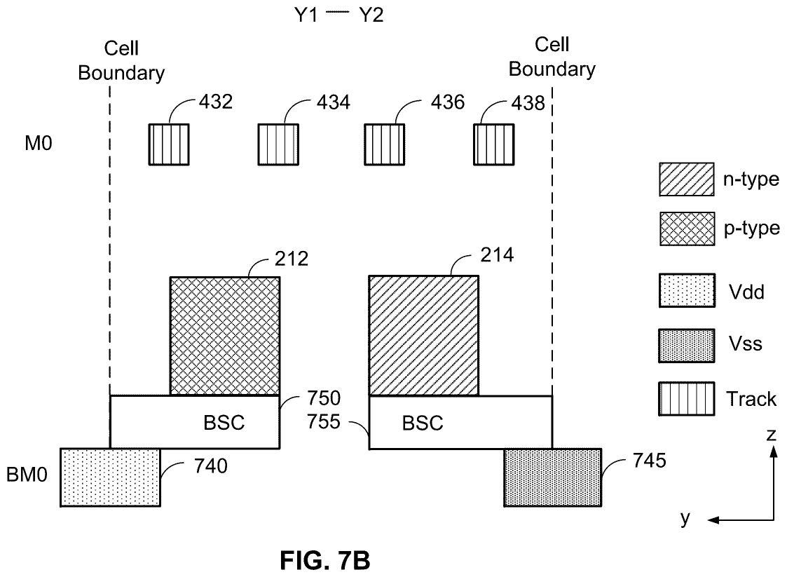

FIG. 7A shows a top view of an example of backside power routing for the cell 210 according to certain aspects. In this example, the backside power routing includes a backside positive supply rail 740 and a backside ground rail 745 in backside metal layer BM0. In FIG. 7A, the diffusion regions 212 and 214 are shown in dotted line to indicate that the diffusion regions 212 and 214 are formed as part of the frontside process. The gates 222, 224, 226, and 228 and the tracks 432, 434, 436, and 438 are not shown in FIG. 7A.

In this example, the backside positive supply rail 740 extends in the x direction and overlaps the top boundary of the cell 210 in the x and y directions, which allows the backside positive supply rail 740 to be shared with an adjacent cell (not shown) located in an adjacent row. The backside ground rail 745 extends in the x direction and overlaps the bottom boundary of the cell 210 in the x and y directions, which allows the backside ground rail 745 to be shared with an adjacent cell (not shown) located in an adjacent row. The backside positive supply rail 740 receives the supply voltage Vdd from the backside distribution network formed in the backside layers 155 (shown in FIGS. 1D and 1E).

FIG. 7B shows a cross-sectional view of the tracks 432, 434, 436, and 438, the diffusion regions 212 and 214, the backside positive supply rail 740, and the backside ground rail 745 taken along line Y1-Y2 in FIGS. 6 and 7A. In this example, the p-type diffusion region 212 is coupled to the backside positive supply rail 740 through a first backside contact 750. The first backside contact 750 is coupled to a bottom surface of the p-type diffusion region 212 and extends in the y direction to the backside positive supply rail 740. The n-type diffusion region 214 is coupled to the backside ground rail 745 through a second backside contact 755. The second backside contact 755 is coupled to a bottom surface of the n-type diffusion region 214 and extends in the y direction to the backside ground rail 745. In some implementations, the first backside contact 750 may be coupled to the backside positive supply rail 740 through a first backside via (e.g., BVD in FIG. 1E), and the second backside contact 755 may be coupled to the backside ground rail 745 through a second backside via (e.g., BVD in FIG. 1E). Although the backside contacts 750 and 755 are aligned in the x direction in the example shown in FIGS. 7A and 7B, it is to be appreciated that the backside contacts 750 and 755 may be offset from one another in the x direction in other implementations.

In this example, most or all of the substrate 108 is removed and the backside positive supply rail 740 and the backside ground rail 745 are formed under the cell 210. Since most or all of the substrate 108 is removed, the n-well 310 and the p-well 320 in FIGS. 3A and 3B may be omitted, which eliminates the restrictions on cell placement due to the n-well 310 and the p-well 320.

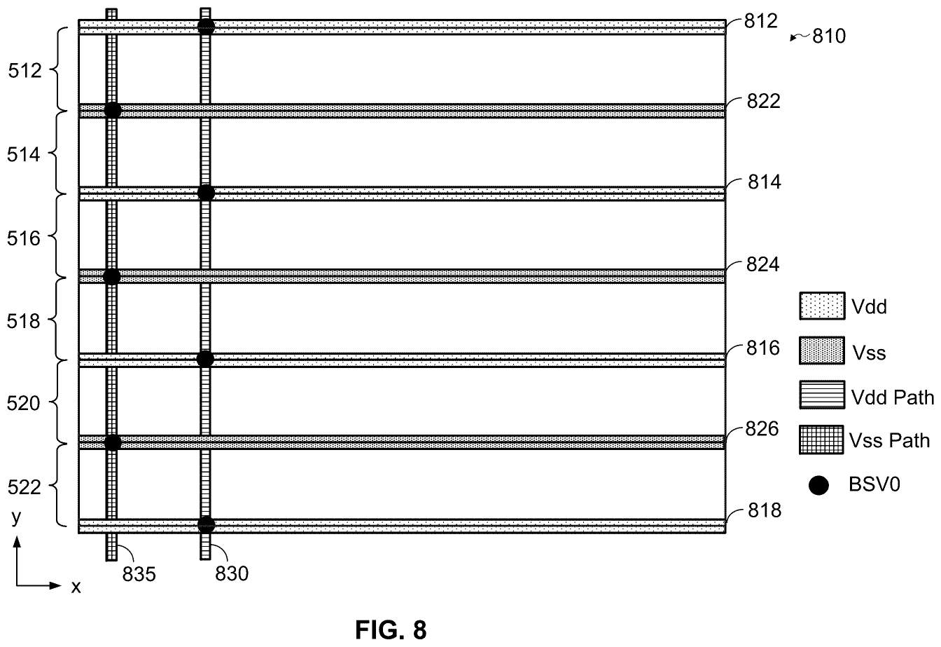

FIG. 8 shows an exemplary layout 810 for backside power routing in backside metal layers BM0 and BM1 for the rows 512, 514, 516, 518, 520, and 522 according to certain aspects of the present disclosure. In this example, the backside power routing includes backside positive supply rails 812, 814, 816, and 818 in backside metal layer BM0, and backside ground rails 822, 824, and 826 in backside metal layer BM0. Each of the backside rails 812, 814, 816, 818, 822, 824, and 826 extends in the x direction. In this example, each of the backside rails 812, 814, 816, 818, 822, 824, and 826 lies along the boundaries of two rows, allowing each of the backside rails 812, 814, 816, 818, 822, 824, and 826 to be shared by cells in two rows.

In the example in FIG. 8, the backside power routing also includes a backside positive supply path 830 in backside metal layer BM1 and a backside ground path 835 in backside metal layer BM1. The positive supply path 830 extends in the y direction under the backside positive supply rails 812, 814, 816, and 818. Each of backside positive supply rails 812, 814, 816, and 818 is coupled to the backside positive supply path 830 by a respective backside via (BSV0 in FIGS. 1D and 1E) disposed between the backside positive supply rail and the backside positive supply path 830. The backside vias are depicted as black circles in FIG. 8. The backside positive supply path 830 distributes the supply voltage Vdd to the backside positive supply rails 812, 814, 816, and 818.

The ground path 835 extends in the y direction under the backside ground rails 822, 824, and 826. Each of backside ground rails 822, 824, and 826 is coupled to the backside ground path 835 by a respective backside via (BSV0 in FIGS. 1D and 1E) disposed between the backside ground rail and the backside ground path 835. The backside vias are depicted as black circles in FIG. 8.

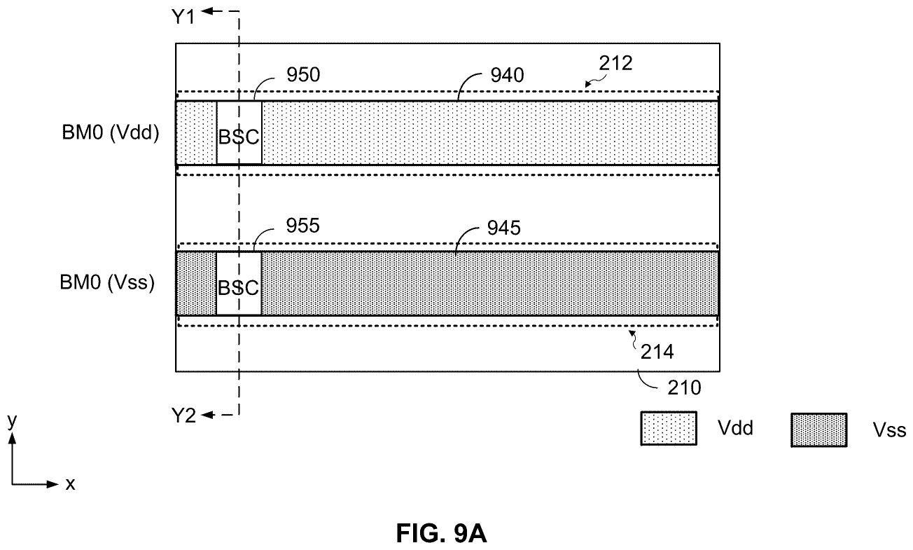

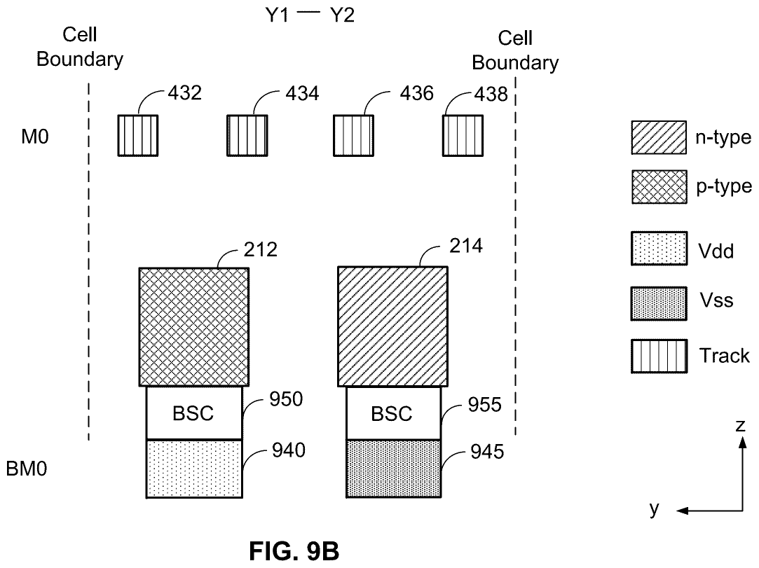

FIG. 9A shows a top view of another example of backside power routing for the cell 210 according to certain aspects. In this example, the backside power routing includes a backside positive supply rail 940 and a backside ground rail 945 in backside metal layer BM0. In FIG. 9A, the diffusion regions 212 and 214 are shown in dotted line. The gates 222, 224, 226, and 228 and the tracks 432, 434, 436, and 438 are not shown in FIG. 9A.

In this example, most or all of the substrate 108 is removed and the backside positive supply rail 940 and the backside ground rail 945 are formed under the cell 210. Since most or all of the substrate 108 is removed, the n-well 310 and the p-well 320 in FIGS. 3A and 3B may be omitted, which eliminates the restrictions on cell placement due to the n-well 310 and the p-well 320.

In this example, the backside positive supply rail 940 extends in the x direction under the p-type diffusion region 212, and the backside ground rail 945 extends in the x direction under the n-type diffusion region 214. The backside positive supply rail 940 receives the supply voltage Vdd from a backside power distribution formed in the backside layers 155 (shown in FIGS. 1D and 1E). In this example, the backside positive supply rail 940 and the backside ground rail 945 are internal rails located within the boundary of the cell 210.

FIG. 9B shows a cross-sectional view of the tracks 432, 434, 436, and 438, the diffusion regions 212 and 214, the backside positive supply rail 940, and the backside ground rail 945 taken along line Y1-Y2 in FIGS. 6 and 9A. In this example, the p-type diffusion region 212 is coupled to the backside positive supply rail 940 through a first backside contact 950 disposed between the p-type diffusion region 212 and the backside positive supply rail 940. The n-type diffusion region 214 is coupled to the backside ground rail 945 through a second backside contact 955 disposed between the n-type diffusion region 214 and the backside ground rail 945. In some implementations, the first backside contact 950 may be coupled to the backside positive supply rail 940 through a first backside via (e.g., BVD in FIG. 1E), and the second backside contact 955 may be coupled to the backside ground rail 945 through a second backside via (e.g., BVD in FIG. 1E). It is to be appreciated that the backside rails 940 and 945 may be wider in the y direction than shown in FIGS. 9A and 9B in some implementations.

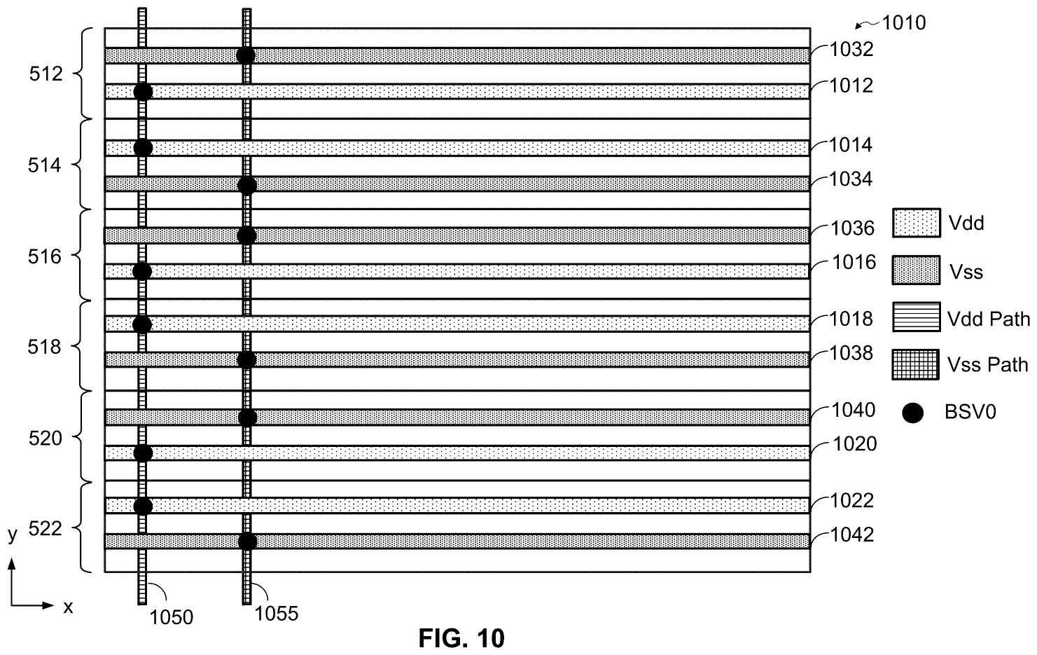

FIG. 10 shows an exemplary layout 1010 for backside power routing in backside metal layers BM0 and BM1 for the rows 512, 514, 516, 518, 520, and 522 according to certain aspects of the present disclosure. In this example, the backside power routing includes backside positive supply rails 1012, 1014, 1016, 1018, 1020, and 1022 in backside metal layer BM0, and backside ground rails 1032, 1034, 1036, 1038, 1040, and 1042 in backside metal layer BM0. Each of the backside rails 1012, 1012, 1014, 1016, 1018, 1020, 1022, 1032, 1034, 1036, 1038, 1040, and 1042 extends in the x direction.

In this example, a respective pair of the backside rails 1012, 1012, 1014, 1016, 1018, 1020, 1022, 1032, 1034, 1036, 1038, 1040, and 1042 is located within each of the rows 512, 514, 516, 518, 520, and 522. More particularly, the backside positive supply rail 1012 and the backside ground rail 1032 are located within the row 512, the backside positive supply rail 1014 and the backside ground rail 1034 are located within the row 514, the backside positive supply rail 1016 and the backside ground rail 1036 are located within the row 516, the backside positive supply rail 1018 and the backside ground rail 1038 are located within the row 518, the backside positive supply rail 1020 and the backside ground rail 1040 are located within the row 520, and the backside positive supply rail 1022 and the backside ground rail 1042 are located within the row 522. Thus, in this example, the backside power routing includes two internal rails (i.e., dual internal rails) for each of the rows 512, 514, 516, 518, 520, and 522.

In the example in FIG. 10, the backside power routing also includes a backside positive supply path 1050 in backside metal layer BM1 and a backside ground path 1055 in backside metal layer BM1. The backside positive supply path 1050 extends in the y direction under the backside positive supply rails 1012, 1014, 1016, 1018, 1020, and 1022. Each of backside positive supply rails 1012, 1014, 1016, 1018, 1020, and 1022 is coupled to the backside positive supply path 1050 by a respective backside via (BSV0 in FIGS. 1D and 1E) disposed between the backside positive supply rail and the backside positive supply path 1050. The backside vias are depicted as black circles in FIG. 10. The backside positive supply path 1050 distributes the supply voltage Vdd to the backside positive supply rails 1012, 1014, 1016, 1018, 1020, and 1022.

The backside ground path 1055 extends in the y direction under the backside ground rails 1032, 1034, 1036, 1038, 1040, and 1042. Each of backside ground rails 1032, 1034, 1036, 1038, 1040, 1042 is coupled to the backside ground path 1055 by a respective backside via (BSV0 in FIGS. 1D and 1E) disposed between the backside ground rail and the backside ground path 1055. The backside vias are depicted as black circles in FIG. 10. The backside ground path 1055 couples the backside ground rails 1032, 1034, 1036, 1038, 1040, and 1042 to a ground.

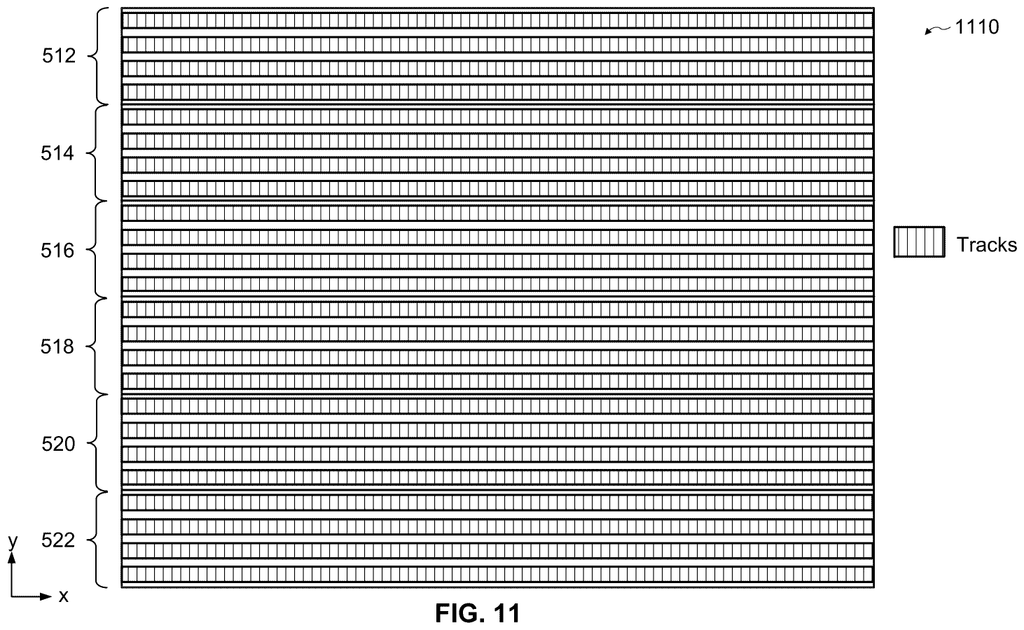

FIG. 11 shows a top view of an exemplary layout 1110 for frontside signal routing in metal layer M0 for the cells in the rows 512, 514, 516, 518, 520, and 522. In this example, each of the tracks is elongated and extends in the x direction, and the tracks are spaced apart in the y direction by a uniform pitch.

In the example in FIG. 11, the layout 1110 includes four tracks within each of the rows 512, 514, 516, 518, 520, and 522. However, it is to be appreciated that the present disclosure is not limited to this example. Although not shown in FIG. 11, it is to be appreciated that the tracks (e.g., four tracks) in each of the rows 512, 514, 516, 518, 520, and 522 may be cut between the cells in the row to provide separate inputs and outputs for the cells.

In this example, power is routed to the cells in the rows 512, 514, 516, 518, 520, and 522 from the backside using a BSPDN (not shown in FIG. 11). In some implementations, the BSPDN may include the exemplary layout 810 of backside positive supply rails 812, 814, and 816 and backside ground rails 822, 824, 826, and 828 shown in FIG. 8. In other implementations, the BSPDN may include the exemplary layout 1010 of backside positive supply rails 1012, 1014, 1016, 1018, 1020, and 1022 and backside ground rails 1032, 1034, 1036, 1038, 1040, and 1042 shown in FIG. 10. In other words, the exemplary layout 1110 for frontside signal routing may be used in combination with either one of the exemplary layouts 810 and 1010 for backside power routing.

In certain aspects, the chip 100 includes cells of various heights in the y direction. For example, the chip 100 may include cells (e.g., high performance cells) having diffusion regions that are wider in the y direction than the diffusion regions of a single-row cell (e.g., the cell 210). The wider diffusion regions provide higher performance (e.g., larger drive strength). The chip 100 may also include cells having diffusion regions that are narrower in the y direction than the diffusion regions of a single-row cell (e.g., the cell 210).

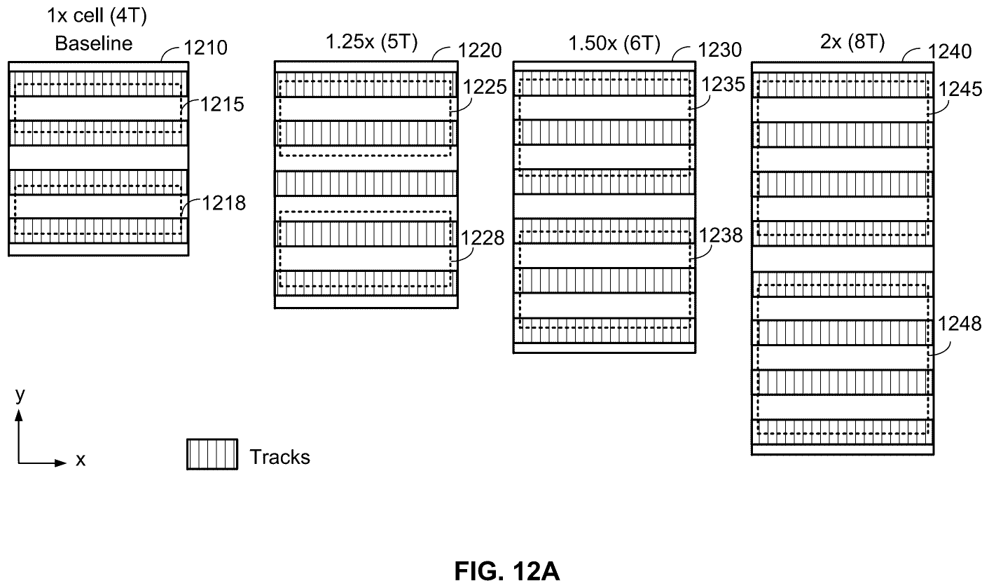

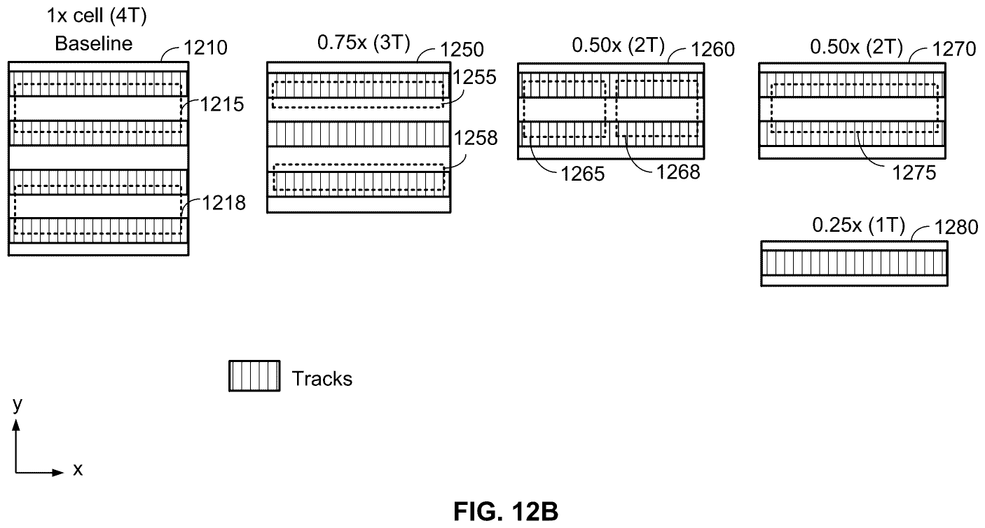

In this regard, FIG. 12A shows an example of various cell heights according to certain aspects. FIG. 12A shows an exemplary layout of a single-row cell 1210 including a first diffusion region 1215 and a second diffusion region 1218. The diffusion regions 1215 and 1218 are shown in dotted line in FIG. 12A. In one example, the single-row cell 1210 corresponds to the cell 210. In this example, the first diffusion region 1215 corresponds to the p-type diffusion region 212 and the second diffusion region 1218 corresponds to the n-type diffusion region 214, or the first diffusion region 1215 corresponds to the n-type diffusion region 214 and the second diffusion region 1218 corresponds to the p-type diffusion region 212 (e.g., depending on whether the orientation in FIG. 2A or the orientation in FIG. 2B is used).

FIG. 12A also shows an example of tracks in metal layer M0 extending in the x direction above the cell 1210. The tracks in FIG. 12A may correspond to the tracks 432, 434, 436, and 438 shown in FIG. 6. In this example, the tracks are spaced apart in the y direction by a uniform pitch. In the example in FIG. 12A, there are four tracks within the boundary of the cell 1210. However, it is to be appreciated that the present disclosure is not limited to this example.

FIG. 12A also shows examples of high-performance cells 1220, 1230, and 1240 having taller heights in the y direction than the single-row cell 1210. In FIG. 12A, the heights of the high-performance cells 1220, 1230, and 1240 are given with respect to the height of the cell 1210, which has a baseline height of 1× in this example.

In the example in FIG. 12A, the high-performance cell 1220 has a height of 1.25× (i.e., 1.25 times the height of the cell 1210). The cell 1220 includes a first diffusion region 1225 and a second diffusion region 1228 where each of the diffusion regions 1225 and 1228 is wider in the y direction than each of the diffusion regions 1215 and 1218 of the cell 1210. The first diffusion region 1225 may be a p-type diffusion region and the second diffusion region 1228 may be an n-type diffusion region, or vice versa. In this example, five tracks in metal layer M0 extend over the cell 1220 to provide signal routing for the cell 1220. The tracks extending over the cell 1220 may be spaced apart in the y direction by the same pitch used for the tracks extending over the cell 1210. The same track pitch allows the same track pattern to be used for both cells 1210 and 1220.

The high-performance cell 1230 has a height of 1.5× (i.e., 1.5 times the height of the cell 1210). The cell 1230 includes a first diffusion region 1235 and a second diffusion region 1238 where each of the diffusion regions 1235 and 1238 is wider in the y direction than each of the diffusion regions 1215 and 1218 of the cell 1210 and each of the diffusion regions 1225 and 1228 of the cell 1220. The first diffusion region 1235 may be a p-type diffusion region and the second diffusion region 1238 may be an n-type diffusion region, or vice versa. In this example, six tracks in metal layer M0 extend over the cell 1230 to provide signal routing for the cell 1230. The tracks extending over the cell 1230 may be spaced apart in the y direction by the same pitch used for the tracks extending over the cells 1210 and 1220. The same track pitch allows the same track pattern to be used for the cells 1210, 1220, and 1230.

The high-performance cell 1240 has a height of 2× (i.e., 2 times the height of the cell 1210). The cell 1240 includes a first diffusion region 1245 and a second diffusion region 1248 where each of the diffusion regions 1245 and 1248 is wider in the y direction than each of the diffusion regions 1215 and 1218 of the cell 1210, each of the diffusion regions 1225 and 1228 of the cell 1220, and each of the diffusion regions 1235 and 1238 of the cell 1230. The first diffusion region 1245 may be a p-type diffusion region and the second diffusion region 1248 may be an n-type diffusion region, or vice versa. In this example, eight tracks in metal layer M0 extend over the cell 1240 to provide signal routing for the cell 1240. The tracks extending over the cell 1240 may be spaced apart in the y direction by the same pitch used for the tracks extending over the cells 1210, 1220, and 1230. The same track pitch allows the same track pattern to be used for the cells 1210, 1220, 1230, and 1240.

Although FIG. 12A shows the cells 1210, 1220, 1230, and 1240 having approximately the same width in the x direction, it is to be appreciated that this need not be the case. For example, the widths of the cells 1210, 1220, 1230, and 1240 may vary in the x direction in some implementations. For example, the widths of the cells 1210, 1220, 1230, and 1240 may vary depending on the number of gates in each cell.

FIG. 12B shows examples of cells 1250, 1260, 1270, and 1280 having shorter heights in the y direction than the single-row cell 1210. In FIG. 12B, the heights of the cells 1250, 1260, 1270, and 1280 are given with respect to the baseline height of 1× (i.e., height of the cell 1210 in this example).

In the example in FIG. 12B, the cell 1250 has a height of 0.75× (i.e., 0.75 times the height of the cell 1210). The cell 1250 includes a first diffusion region 1255 and a second diffusion region 1258 where each of the diffusion regions 1255 and 1258 is narrower in the y direction than each of the diffusion regions 1215 and 1218 of the cell 1210. The first diffusion region 1255 may be a p-type diffusion region and the second diffusion region 1258 may be an n-type diffusion region, or vice versa. In this example, three tracks in metal layer M0 extend over the cell 1250 to provide signal routing for the cell 1250. The tracks extending over the cell 1250 may be spaced apart in the y direction by the same pitch used for the tracks extending over the cell 1210.

In the example in FIG. 12B, the cell 1260 has a height of 0.5× (i.e., 0.5 times the height of the cell 1210). The cell 1260 includes a first diffusion region 1265 and a second diffusion region 1268. The first diffusion region 1265 may be a p-type diffusion region and the second diffusion region 1268 may be an n-type diffusion region, or vice versa. In this example, the first diffusion region 1265 and the second diffusion region 1268 are arranged side-by-side in the x direction. In this example, two tracks in metal layer M0 extend over the cell 1260 to provide signal routing for the cell 1260. The tracks extending over the cell 1260 may be spaced apart in the y direction by the same pitch used for the tracks extending over the cell 1210.

In the example in FIG. 12B, the cell 1270 has a height of 0.5× (i.e., 0.5 times the height of the cell 1210). The cell 1270 includes a diffusion region 1275 which may include a p-type diffusion region or an n-type diffusion region. In this example, two tracks in metal layer M0 extend over the cell 1270 in which the tracks may be spaced apart in the y direction by the same pitch used for the tracks extending over the cell 1210. In this example, the cell 1270 may be used, for example, as a filler cell for filling an empty space (e.g., between standard cells) having a height of 0.5×.

In the example in FIG. 12B, the cell 1280 has a height of 0.25× (i.e., 0.25 times the height of the cell 1210). In this example, one track in metal layer M0 extends over the cell 1280. The cell 1280 may be used, for example, as a filler cell for filling an empty space (e.g., between standard cells) having a height of 0.25×.

Although FIG. 12B shows the cells 1210, 1250, 1260, 1270, and 1280 having approximately the same width in the x direction, it is to be appreciated that this need not be the case. For example, the widths of the cells 1210, 1250, 1260, 1270, and 1280 may vary in the x direction in some implementations.

Each of the diffusion regions 1215, 1218, 1225, 1228, 1235, 1238, 1245, 1248, 1255, 1258, 1265, 1268, and 1275 in FIGS. 12A and 12B may include one or more epi layers (e.g., one or more instances of the epi layers 114 and 116) and one or more channels (e.g., one or more instances of the one or more channels 170).

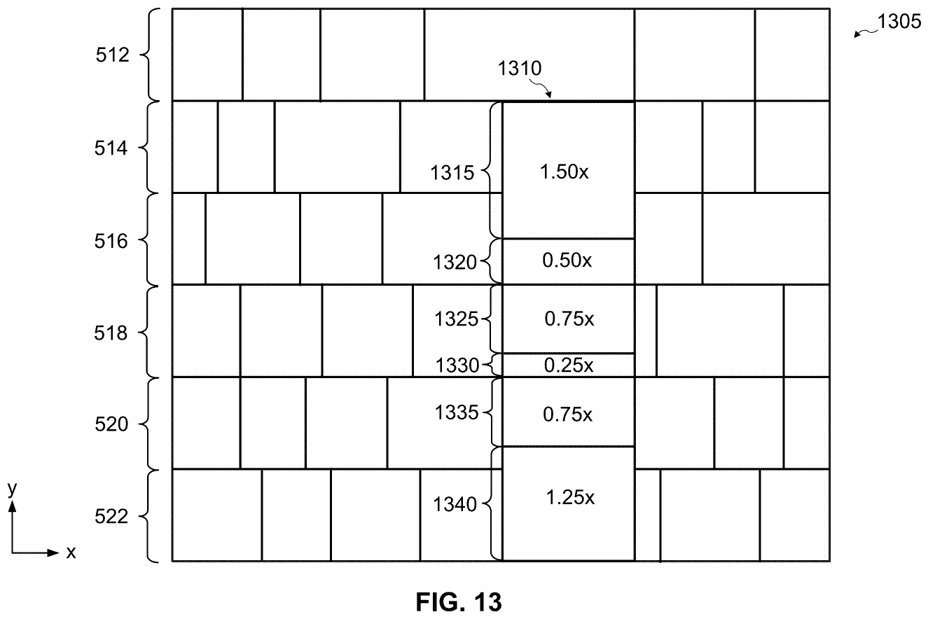

FIG. 13 shows an exemplary layout 1305 facilitating variable cell height integration according to certain aspects. The layout 1305 includes the layout of the rows 512, 514, 516, 518, 520, and 522, which have the same height (i.e., uniform height) in the y direction. The cells in each of the rows 512, 514, 516, 518, 520, and 522 may have the same width in the x direction or varying widths in the x direction (e.g., based on the number of gates in each cell). In FIG. 13, each cell is shown as a rectangular box delineating the boundary of the cell. However, it is to be appreciated that the layout 1305 is not limited to the exemplary cell boundaries shown in FIG. 13.

In this example, each of the rows 512, 514, 516, 518, 520, and 522 may have a height approximately equal to the baseline height of 1× shown in FIGS. 12A and 12B. Thus, in this example, one or more instances of the cell 1210 (which may correspond to the cell 210) may be placed in one or more of the rows 512, 514, 516, 518, 520, and 522.

The layout 1305 also includes a variable-cell-height area 1310 according to certain aspects. As used herein, a “variable-cell-height area” is an area including cells having a variable height (i.e., non-constant height) in the y direction. In this example, the variable-cell-height area 1310 has a rectangular shape. However, it is to be appreciated that the variable-cell-height area 1310 may have other shapes in other implementations. The variable-cell-height area 1310 includes rows 1315, 1320, 1325, 1330, 1335, and 1340 of varying heights to accommodate cells of varying heights. In the example shown in FIG. 13, the row 1315 has a height of 1.50×, the row 1320 has a height of 0.50×, the row 1325 has a height of 0.75×, the row 1330 has a height of 0.25×, the row 1335 has a height of 0.75×, and the row 1340 has a height of 1.25×. Thus, in this example, the row 1315 accommodates cells having a height of 1.50×, the row 1320 accommodates cells having a height of 0.50×, the rows 1325 and 1335 accommodate cells having a height of 0.75×, the row 1330 accommodate cells having a height of 0.25×, and the row 1340 accommodate cells having a height of 1.25×. However, it is to be appreciated that the variable-cell-height area 1310 is not limited to this example, and that the variable-cell-height area 1310 may have a mix of other row heights in other examples.

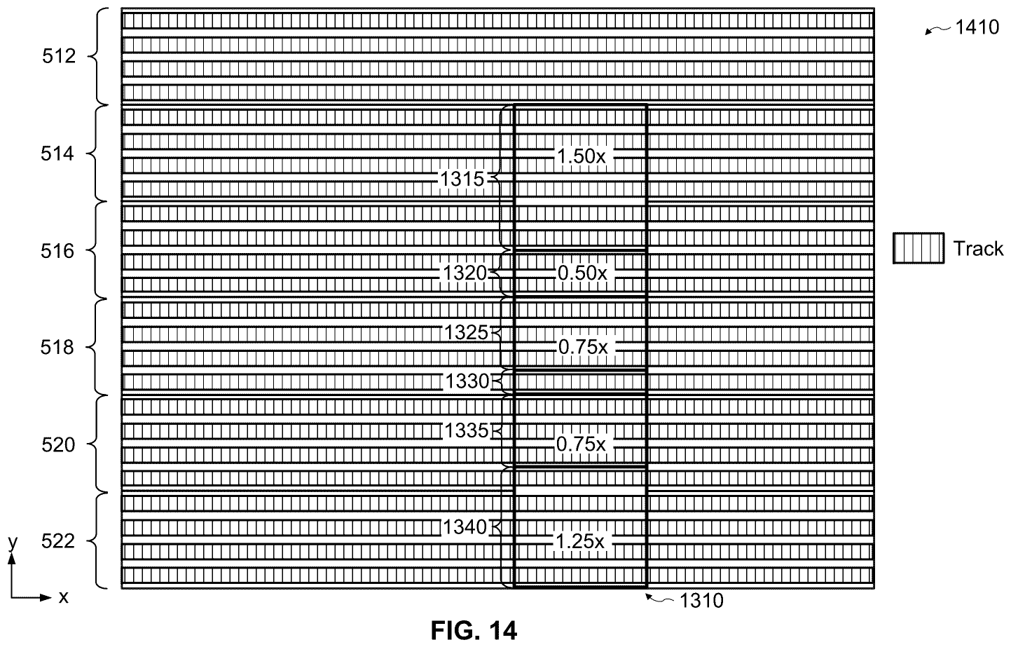

FIG. 14 shows an exemplary track layout 1410 in metal layer M0 for providing frontside signal routing for the cells in the rows 512, 514, 516, 518, 520, and 522 and the cells in the rows 1315, 1320, 1325, 1330, 1335, and 1340. Each of the tracks is elongated and extends in the x direction. The tracks are spaced apart in the y direction by a uniform pitch.

In the example in FIG. 14, the layout 1410 includes four tracks within each of the rows 512, 514, 516, 518, 520, and 522, in which each of the rows 512, 514, 516, 518, 520, and 522 has a height of approximately 1× in this example. The layout 1410 also includes six tracks within the row 1315 (which has a height of 1.50×), two tracks within the row 1320 (which has a height of 0.50×), three tracks within each of the rows 1325 and 1335 (which each has a height of 0.75×), one track within the row 1330 (which has a height of 0.25×), and five tracks within the row 1340 (which has a height of 1.25×). Although not shown in FIG. 14, it is to be appreciated that the tracks in each of the rows 512, 514, 516, 518, 520, 522, 1315, 1320, 1325, 1330, 1335, and 1340 may be cut between the cells in the row to provide separate inputs and outputs for the cells in the row. Since the tracks are spaced apart by a uniform pitch throughout the track layout 1410, the same track pattern may be used for the rows 512, 514, 516, 518, 520, 522, 1315, 1320, 1325, 1330, 1335, and 1340, which reduces processing cost.

In this example, power is routed to the cells in the rows 512, 514, 516, 518, 520, 522, 1315, 1320, 1325, 1330, 1335, and 1340 from the backside using a BSPDN (not shown in FIG. 14). Since power is routing from the backside in this example, the layout 1410 does not include positive supply rails and ground rails in metal layer M0.

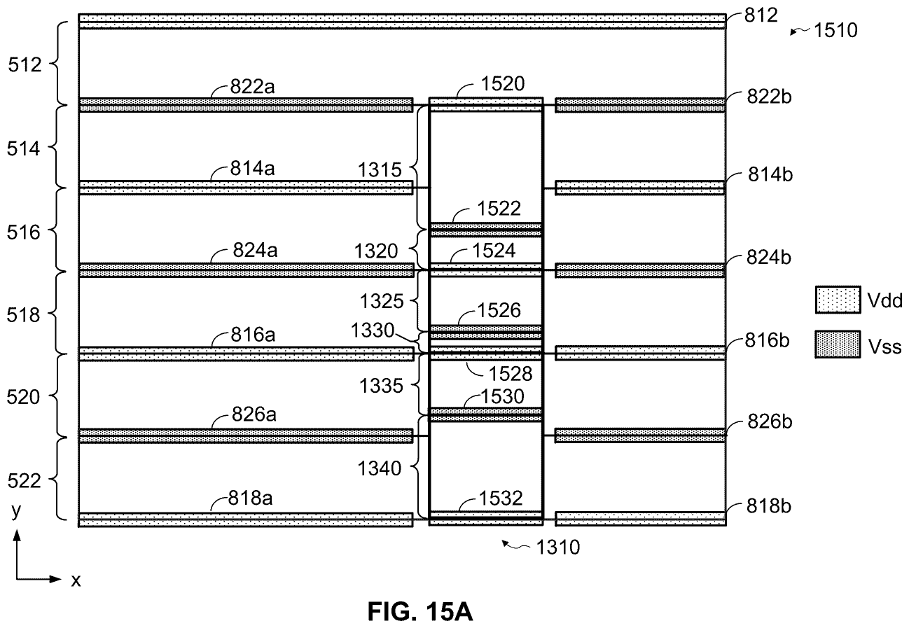

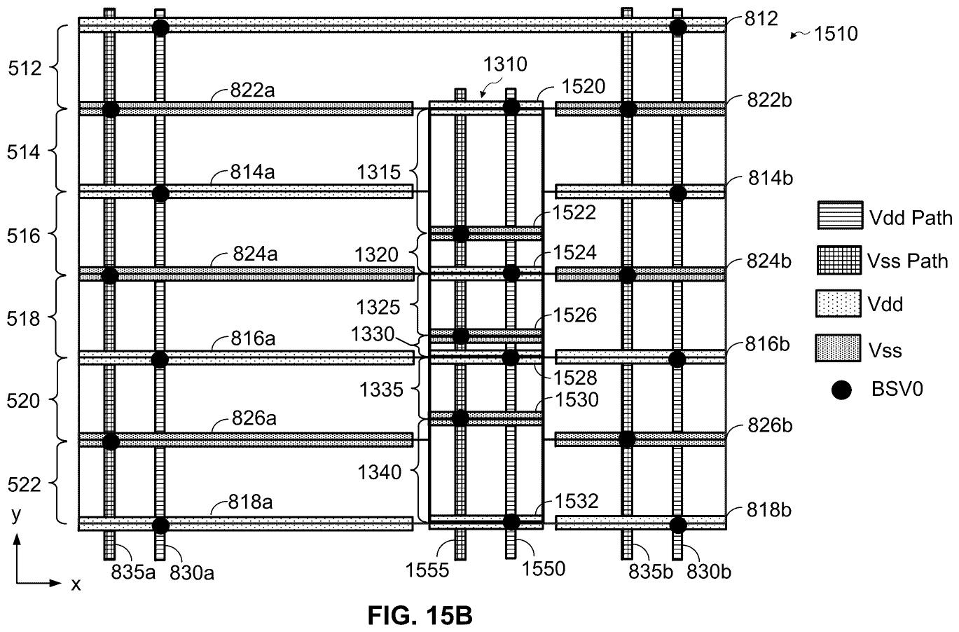

FIG. 15A shows an exemplary layout 1510 for backside power routing in backside metal layer BM0 for the rows 512, 514, 516, 518, 520, 522, 1315, 1320, 1325, 1330, 1335, and 1340 according to certain aspects of the present disclosure. In this example, the backside positive supply rails 814, 816, and 818 are split into positive supply rails 814a, 814b, 816a, 816b, 818a, and 818b, and the backside ground rails 822, 824, and 826 are split into ground rails 822a, 822b, 824a, 824b, 826a, and 826b to make room for the variable-cell-height area 1310. Each of the rails 812, 814a, 814b, 816a, 816b, 818a, 818b, 822a, 822b, 824a, 824b, 826a, and 826b lies along the boundaries of two rows. In this example, the rails 812, 814a, 814b, 816a, 816b, 818a, 818b, 822a, 822b, 824a, 824b, 826a, and 826b are spaced apart in the y direction by a uniform pitch (e.g., approximately 1×).

The layout 1510 also includes backside positive supply rails 1520, 1524, 1528, and 1532 in backside metal layer BM0, and backside ground rails 1522, 1526, and 1530 in backside metal layer BM0. In this example, the pitch between the rails 1520, 1522, 1524, 1526, 1528, 1530, and 1532 varies in the y direction to accommodate cells of varying heights. In other words, the rails 1520, 1522, 1524, 1526, 1528, 1530, and 1532 are spaced apart by a variable pitch (i.e., non-uniform or non-constant pitch) in the y direction to accommodate cells of varying heights.

In the example in FIG. 15A, the positive supply rail 1520 overlaps the top boundary of the row 1315 and the ground rail 1522 overlaps the bottom boundary of the row 1315. The positive supply rail 1520 and the ground rail 1522 provide backside power routing for cells in the row 1315. The ground rail 1522 overlaps the top boundary of the row 1320 and the positive supply rail 1524 overlaps the bottom boundary of the row 1320. The ground rail 1522 and the positive supply rail 1524 provide power routing for cells in the row 1320. In this example, the pitch between the ground rail 1522 and the positive supply rail 1524 is smaller than the pitch between the positive supply rail 1520 and the ground rail 1522 since the row 1315 (which accommodates 1.5× cells) is taller than the row 1320 (which accommodates 0.5× cells).

The positive supply rail 1524 overlaps the top boundary of the row 1325 and the ground rail 1526 overlaps the bottom boundary of the row 1325. The positive supply rail 1524 and the ground rail 1526 provide backside power routing for cells in the row 1325. In this example, the pitch between the positive supply rail 1524 and the ground rail 1526 is larger than the pitch between the ground rail 1522 and the positive supply rail 1524 since the row 1325 is taller than the row 1320.

The ground rail 1526 overlaps the top boundary of the row 1330 and the positive supply rail 1528 overlaps the bottom boundary of the row 1330. The row 1330 may include 0.25× filler cells (e.g., the cell 1280).

The positive supply rail 1528 overlaps the top boundary of the row 1335 and the ground rail 1530 overlaps the bottom boundary of the row 1335. The positive supply rail 1528 and the ground rail 1530 provide backside power routing for the cells in row 1335. The ground rail 1530 overlaps the top boundary of the row 1340 and the positive supply rail 1532 overlaps the bottom boundary of the row 1340. The ground rail 1530 and the positive supply rail 1532 provide backside power routing for the cells in the row 1340. In this example, the pitch between the ground rail 1530 and the positive supply rail 1532 is larger than the pitch between the positive supply rail 1528 and the ground rail 1530 since the row 1340 is taller than the row 1335.

In the example in FIG. 15A, the backside rails 822a, 814a, 824a, 816a, 826a, and 818a are arranged in a first column, the backside rails 1520, 1522, 1524, 1526, 1528, 1530, and 1532 are arranged in a second column adjacent to the first column, and the backside rails 822b, 814b, 824b, 816b, 826b, and 818b are arranged in a third column adjacent to the second column, in which the second column is between the first column and the second column. However, it is to be appreciated that the present disclosure is not limited to this example.

In the example in FIG. 15A, the pitch between the rails 1520 and 1522 and the pitch between the rails 1530 and 1532 are each greater than the uniform pitch (e.g., 1×), and the pitch between the rails 1522 and 1524, the pitch between the rails 1524 and 1526, the pitch between the rails 1526 and 1528, and the pitch between rails 1528 and 1530 are each less than the uniform pitch (e.g., 1×). However, it is to be appreciated that the rails 1520, 1522, 1524, 1526, 1528, 1530, and 1532 are not limited to the exemplary pitches show in FIG. 15A, and that the pitches between these rails may differ from the example shown in FIG. 15A depending, for example, on the heights of the rows 1315, 1320, 1325, 1330, 1335, and 1340.

FIG. 15B shows an example of backside routing in backside metal layer BM1, which is below metal layer BM0. In this example, the backside power routing also includes a first backside positive supply path 830a in backside metal layer BM1 and a first backside ground path 835a in backside metal layer BM1. The first positive supply path 830a extends in the y direction under the backside positive supply rails 812, 814a, 816a, and 818a. Each of backside positive supply rails 812, 814a, 816a, and 818a is coupled to the first backside positive supply path 830a by a respective backside via (BSV0 in FIGS. 1D and 1E) disposed between the backside positive supply rail and the first backside positive supply path 830a. The backside vias are depicted as black circles in FIG. 15B.

The first backside ground path 835a extends in the y direction under the backside ground rails 822a, 824a, and 826a. Each of backside ground rails 822a, 824a, and 826a is coupled to the first backside ground path 835a by a respective backside via (BSV0 in FIGS. 1D and 1E) disposed between the backside ground rail and the first backside ground path 835a. The backside vias are depicted as black circles in FIG. 15B.

The backside power routing also includes a second backside positive supply path 1550 in backside metal layer BM1 and a second backside ground path 1555 in backside metal layer BM1. The second positive supply path 1550 extends in the y direction under the backside positive supply rails 1520, 1524, 1528, and 1532 in the variable-cell-height area 1310. Each of backside positive supply rails 1520, 1524, 1528, and 1532 is coupled to the second backside positive supply path 1550 by a respective backside via (BSV0 in FIGS. 1D and 1E) disposed between the backside positive supply rail and the second backside positive supply path 1550. The backside vias are depicted as black circles in FIG. 15B.

The second backside ground path 1555 extends in the y direction under the backside ground rails 1522, 1526, and 1530. Each of backside ground rails 1522, 1526, and 1530 is coupled to the second backside ground path 1555 by a respective backside via (BSV0 in FIGS. 1D and 1E) disposed between the backside ground rail and the second backside ground path 1555. The backside vias are depicted as black circles in FIG. 15B.

In this example, the second backside positive supply path 1550 and the second backside ground path 1555 allows the backside rails 1520, 1522, 1524, 1526, 1528, 1530, and 1532 within the variable-cell-height area 1310 to be configured (e.g., laid out) independently from the rails outside of the variable-cell-height area 1310 while still receiving power from the BSPDN. In other words, the backside rails 1520, 1522, 1524, 1526, 1528, 1530, and 1532 are powered separately from the rails outside of the variable-cell-height area 1310 by local Vdd/Gnd in backside metal layer BM0 (i.e., the second backside positive supply path 1550 and the second backside ground path 1555).

In this example, the backside power routing also includes a third backside positive supply path 830b in backside metal layer BM1 and a third backside ground path 835b in backside metal layer BM1. The third positive supply path 830b extends in the y direction under the backside positive supply rails 812, 814b, 816b, and 818b. Each of backside positive supply rails 812, 814b, 816b, and 818b is coupled to the third backside positive supply path 830b by a respective backside via (BSV0 in FIGS. 1D and 1E) disposed between the backside positive supply rail and the third backside positive supply path 830b. The backside vias are depicted as black circles in FIG. 15B.

The third backside ground path 835b extends in the y direction under the backside ground rails 822b, 824b, and 826b. Each of backside ground rails 822b, 824b, and 826b is coupled to the third backside ground path 835b by a respective backside via (BSV0 in FIGS. 1D and 1E) disposed between the backside ground rail and the third backside ground path 835b. The backside vias are depicted as black circles in FIG. 15B.

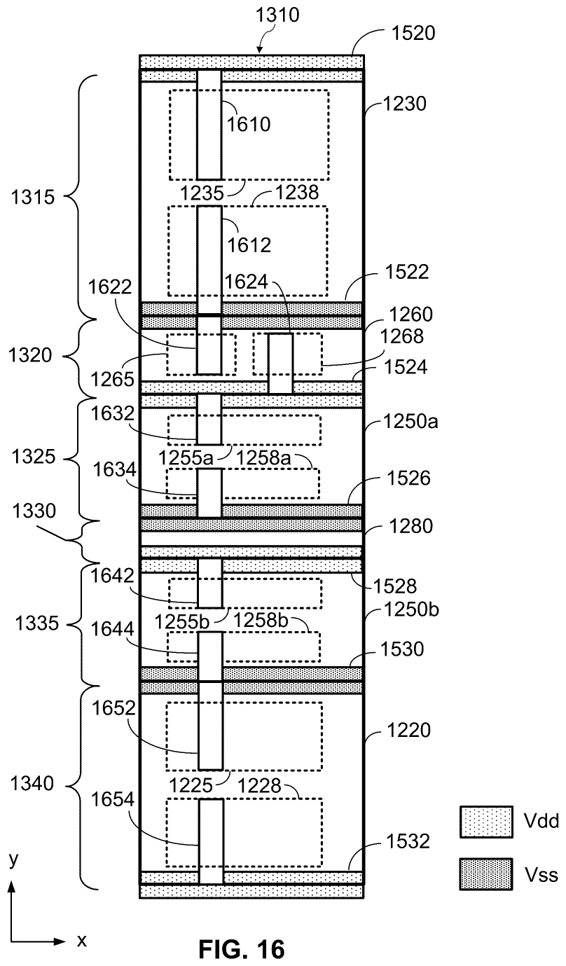

FIG. 16 shows an example of cells with varying heights placed in the rows 1315, 1320, 1325, 1330, 1335, and 1340 according to certain aspects. In this example, the cell 1230 (i.e., 1.50× cell) is placed in the row 1315, the cell 1260 (i.e., 0.5× cell) is placed in the row 1320, the cell 1250a (i.e., 0.75× cell) is placed in the row 1325, the filler cell 1280 is placed in the row 1330, the cell 1250b (i.e., 0.75× cell) is placed in the row 1335, and the cell 1220 (i.e., 1.25× cell) is placed in the row 1340. The cells 1250a and 1250b are separate instances of the cell 1250.

In the example in FIG. 16, the first diffusion region 1235 (e.g., p-type diffusion region) of the cell 1230 is coupled to the backside positive supply rail 1520 by a backside contact 1610 (e.g., BSC in FIGS. 1D and 1E) coupled between the first diffusion region 1235 and the backside positive supply rail 1520. The second diffusion region 1238 (e.g., n-type diffusion region) of the cell 1230 is coupled to the backside ground rail 1522 by a backside contact 1612 (e.g., BSC in FIGS. 1D and 1E) coupled between the second diffusion region 1238 and the backside ground rail 1522.

In this example, the first diffusion region 1265 (e.g., n-type diffusion region) of the cell 1260 is coupled to the backside ground rail 1522 by a backside contact 1622 (e.g., BSC in FIGS. 1D and 1E) coupled between the first diffusion region 1265 and the backside ground rail 1522. The second diffusion region 1268 (e.g., p-type diffusion region) of the cell 1260 is coupled to the backside positive supply rail 1524 by a backside contact 1624 (e.g., BSC in FIGS. 1D and 1E) coupled between the second diffusion region 1268 and the backside positive supply rail 1524.

In this example, the first diffusion region 1255a (e.g., p-type diffusion region) of the cell 1250a is coupled to the backside positive supply rail 1524 by a backside contact 1632 (e.g., BSC in FIGS. 1D and 1E) coupled between the first diffusion region 1255a and the backside positive supply rail 1524. The second diffusion region 1258a (e.g., n-type diffusion region) of the cell 1250a is coupled to the backside ground rail 1526 by a backside contact 1634 (e.g., BSC in FIGS. 1D and 1E) coupled between the second diffusion region 1258a and the backside ground rail 1526.

In this example, the first diffusion region 1255b (e.g., p-type diffusion region) of the cell 1250b is coupled to the backside positive supply rail 1528 by a backside contact 1642 (e.g., BSC in FIGS. 1D and 1E) coupled between the first diffusion region 1255b and the backside positive supply rail 1528. The second diffusion region 1258b (e.g., n-type diffusion region) of the cell 1250b is coupled to the backside ground rail 1530 by a backside contact 1644 (e.g., BSC in FIGS. 1D and 1E) coupled between the second diffusion region 1258b and the backside ground rail 1530.

In this example, the first diffusion region 1225 (e.g., n-type diffusion region) of the cell 1220 is coupled to the backside ground rail 1530 by a backside contact 1652 (e.g., BSC in FIGS. 1D and 1E) coupled between the first diffusion region 1225 and the backside ground rail 1530. The second diffusion region 1228 (e.g., p-type diffusion region) of the cell 1220 is coupled to the backside positive supply rail 1532 by a backside contact 1654 (e.g., BSC in FIGS. 1D and 1E) coupled between the second diffusion region 1228 and the backside positive supply rail 1532.

Although the backside contacts 1610, 1612, 1622, 1632, 1634, 1642, 1644, 1652, and 1654 are shown being aligned in the x direction in the example in FIG. 16, it is to be appreciated that each of the backside contacts 1610, 1612, 1622, 1632, 1634, 1642, 1644, 1652, and 1654 may be placed at another location in the x direction.

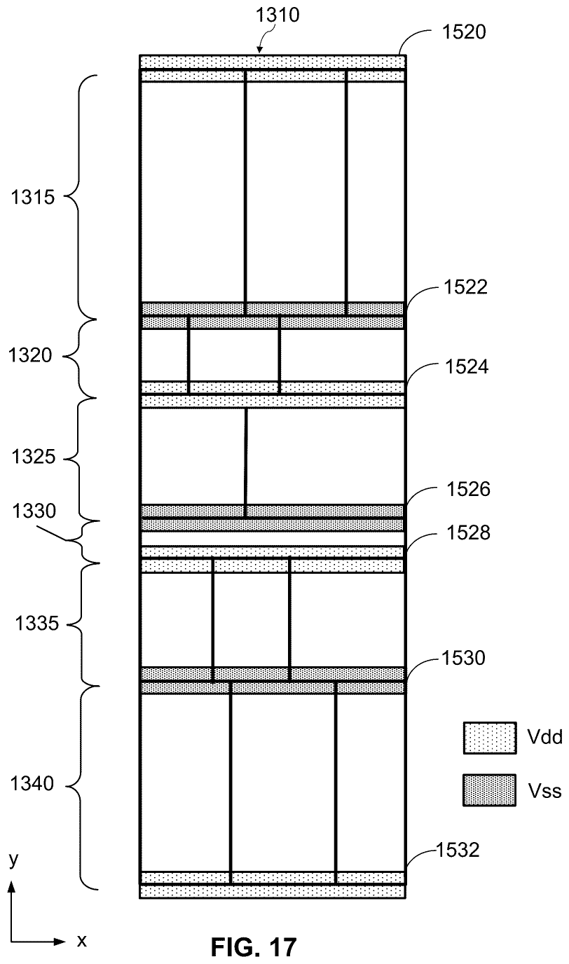

Although FIG. 16 shows one cell placed in each of the rows 1315, 1320, 1325, 1330, 1335, and 1334 for ease of illustration, it is to be appreciated that multiple cells may be placed in each of one or more of the rows 1315, 1320, 1325, 1330, 1335, and 1334. In this regard, FIG. 17 shows an example in which each of the rows 1315, 1320, 1325, 1335, and 1340 includes multiple cells (e.g., multiple cells of varying widths in the x direction).

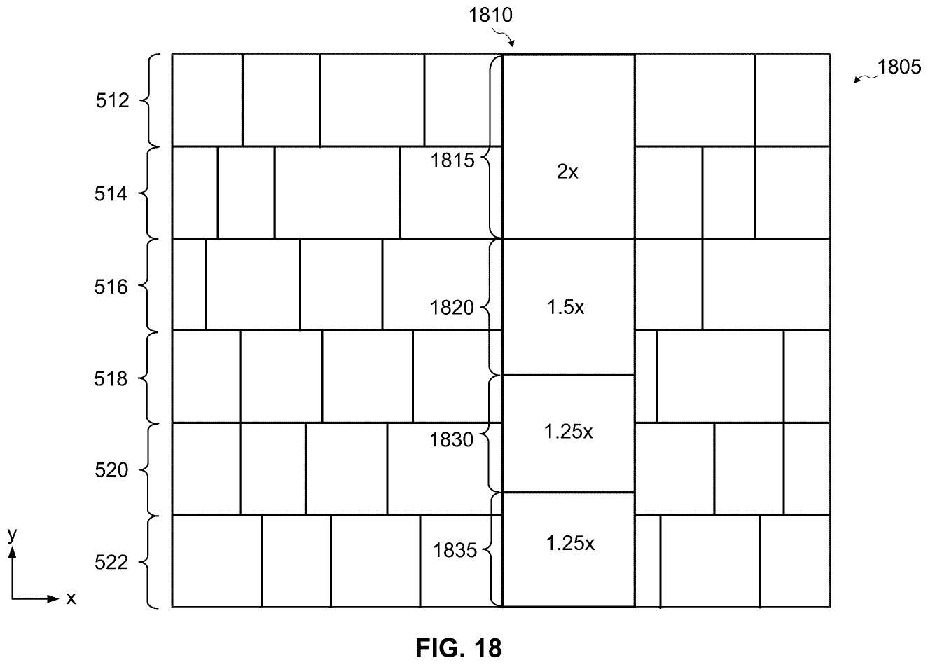

FIG. 18 shows another example of a layout 1805 including a variable-cell-height area 1810 according to certain aspects. In this example, the variable-cell-height area 1810 is in the form of a column. However, it is to be appreciated that the variable-cell-height area 1810 may have other shapes in other implementations. The variable-cell-height area 1810 includes rows 1815, 1820, 1830, and 1835 of varying heights to accommodate cells of varying heights. In the example shown in FIG. 18, the row 1815 has a height of 2×, the row 1820 has a height of 1.5×, the row 1830 has a height of 1.25×, and the row 1835 has a height of 1.25×. Thus, in this example, the row 1815 accommodates cells having a height of 2×, the row 1820 accommodates cells having a height of 1.5×, and the rows 1830 and 1835 accommodate cells having a height of 1.25×. However, it is to be appreciated that the variable-cell-height area 1810 is not limited to this example, and that the variable-cell-height area 1810 may have a mix of other cell heights in other examples. In the example in FIG. 18, the cells in the areas to the left and the right of the variable-cell-height area 1810 have a uniform height in the y direction (e.g., height of 1×).

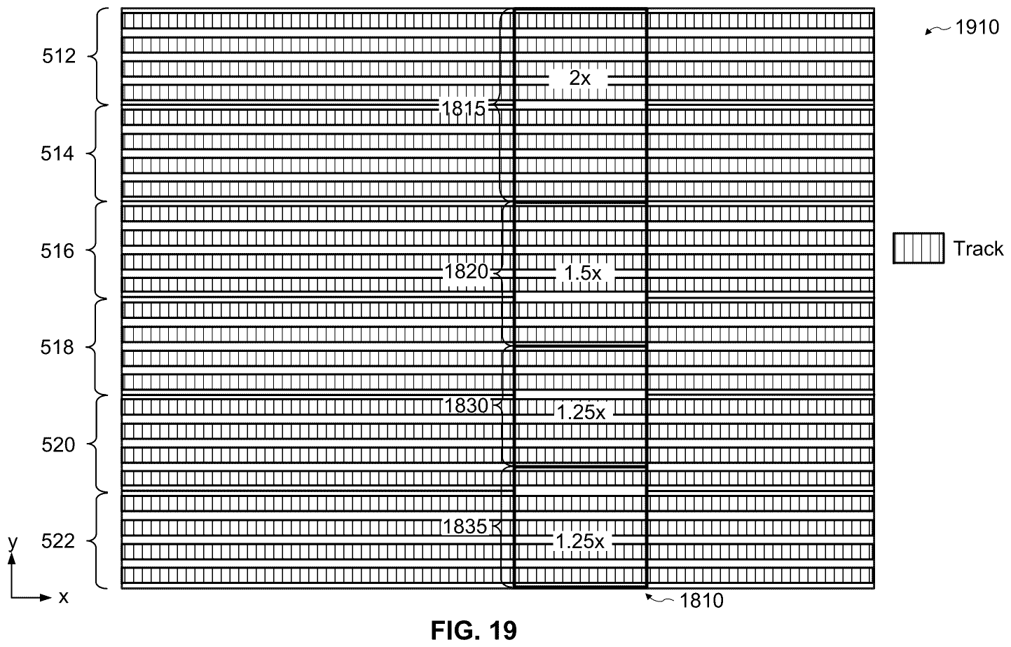

FIG. 19 shows an exemplary track layout 1910 in metal layer M0 for providing frontside signal routing for the cells in the rows 512, 514, 516, 518, 520, and 522 and the cells in the rows 1815, 1820, 1830, and 1835. Each of the tracks is elongated and extends in the x direction. The tracks are spaced apart in the y direction by a uniform pitch.

In the example in FIG. 19, the layout 1910 includes four tracks within each of the rows 512, 514, 516, 518, 520, and 522, in which each of the rows 512, 514, 516, 518, 520, and 522 has a height of approximately 1× in this example. The layout 1910 also includes eighth tracks within the row 1815 (which has a height of 2×), six tracks within the row 1820 (which has a height of 1.5×), and five tracks within each of the rows 1830 and 1835 (which each has a height of 1.25×). Although not shown in FIG. 19, it is to be appreciated that the tracks in each of the rows 512, 514, 516, 518, 520, 522, 1815, 1820, 1830, and 1835 may be cut between the cells in the row to provide separate inputs and outputs for the cells in the row. Since the tracks are spaced apart by a uniform pitch throughout the track layout 1910, the same track pattern may be used for the rows 512, 514, 516, 518, 520, 522, 1815, 1820, 1830, and 1835, which reduces processing cost.

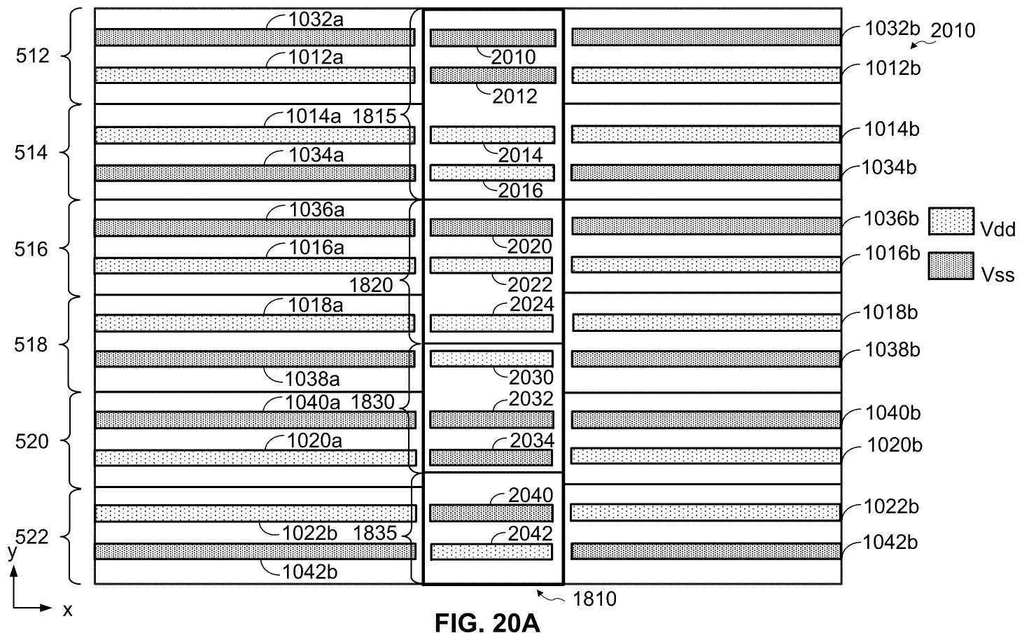

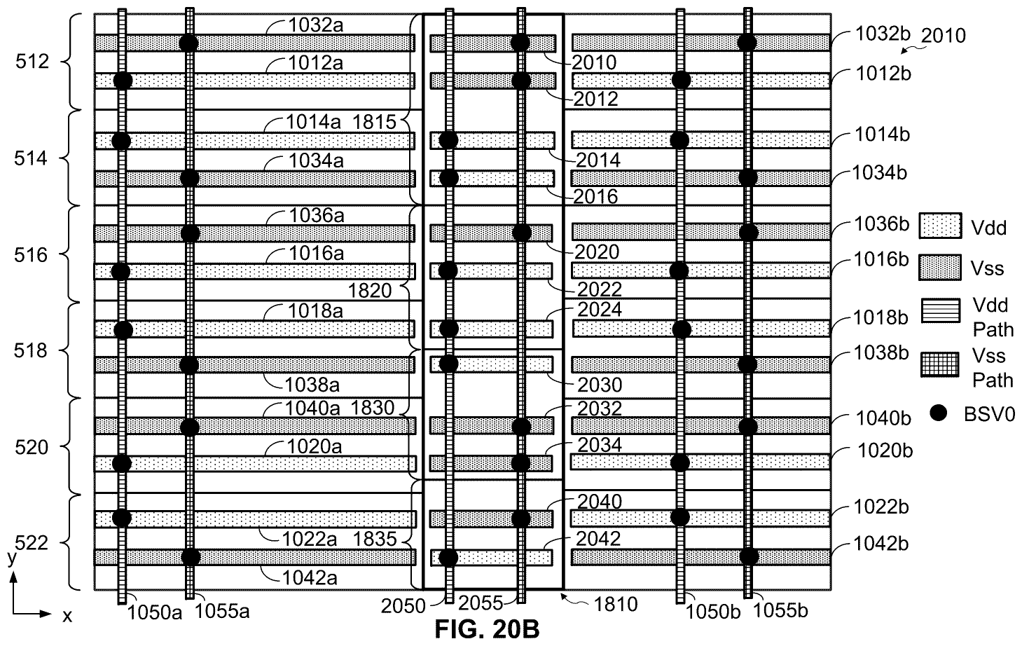

FIG. 20A shows an exemplary layout 2010 for backside power routing in backside metal layer BM0 for the rows 512, 514, 516, 518, 520, 522, 1815, 1820, 1830, and 1835 according to certain aspects of the present disclosure. In this example, power is provided to the rows 512, 514, 516, 518, 520, and 522 from the backside using dual internal rails in each row. In this example, the backside positive supply rails 1012, 1014, 1016, 1018, 1020, and 1022 are split into backside positive supply rails 1012a, 1012b, 1014a, 1014b, 1016a, 1016b, 1018a, 1018b, 1020a, 1020b, 1022a, and 1022b, and the backside ground rails 1032, 1034, 1036, 1038, 1040, and 1042 are split into backside ground rails 1032a, 1032b, 1034a, 1034b, 1036a, 1036b, 1038a, 1038b, 1040a, 1040b, 1042a, and 1042b. This is done to make room for the variable-cell-height area 1810 in this example.

Within the variable-cell-height area 1810, the layout 2010 also includes backside positive supply rails 2014, 2016, 2022, 2024, 2030, and 2042 in backside metal layer BM0, and backside ground rails 2010, 2012, 2020, 2032, 2034, and 2040 in backside metal layer BM0. In this example, the backside positive supply rails 2014 and 2016 and the backside ground rails 2010 and 2012 are within the row 1815. The backside positive supply rails 2022 and 2024 and the backside ground rail 2020 are within the row 1820. The backside positive supply rails 2030 and the backside ground rails 2032 and 2034 are within the row 1830. The backside positive supply rails 2042 and the backside ground rail 2040 are within the row 1835.

FIG. 20B shows an example of backside routing in backside metal layer BM1, which is below metal layer BM0. In this example, the backside power routing also includes a first backside positive supply path 1050a in backside metal layer BM1 and a first backside ground path 1055a in backside metal layer BM1. The first positive supply path 1050a extends in the y direction under the backside positive supply rails 1012a, 1014a, 1016a, 1018a, 1020a, and 1022a. Each of backside positive supply rails 1012a, 1014a, 1016a, 1018a, 1020a, and 1022a is coupled to the first backside positive supply path 1050a by a respective backside via (BSV0 in FIGS. 1D and 1E) disposed between the backside positive supply rail and the first backside positive supply path 1050a. The backside vias are depicted as black circles in FIG. 20B.

The first backside ground path 1055a extends in the y direction under the backside ground rails 1032a, 1034a, 1036a, 1038a, 1040a, and 1042a. Each of backside ground rails 1032a, 1034a, 1036a, 1038a, 1040a, and 1042a is coupled to the first backside ground path 1055a by a respective backside via (BSV0 in FIGS. 1D and 1E) disposed between the backside ground rail and the first backside ground path 1055a. The backside vias are depicted as black circles in FIG. 20B.

The backside power routing also includes a second backside positive supply path 2050 in backside metal layer BM1 and a second backside ground path 2055 in backside metal layer BM1. The second positive supply path 2050 extends in the y direction under the backside positive supply rails 2014, 2016, 2022, 2024, 2030, and 2042 in the variable-cell-height area 1810. Each of backside positive supply rails 2014, 2016, 2022, 2024, 2030, and 2042 is coupled to the second backside positive supply path 2050 by a respective backside via (BSV0 in FIGS. 1D and 1E) disposed between the backside positive supply rail and the second backside positive supply path 2050. The backside vias are depicted as black circles in FIG. 20B.

The second backside ground path 2055 extends in the y direction under the backside ground rails 2010, 2012, 2020, 2032, 2034, and 2040. Each of backside ground rails 2010, 2012, 2020, 2032, 2034, and 2040 is coupled to the second backside ground path 2055 by a respective backside via (BSV0 in FIGS. 1D and 1E) disposed between the backside ground rail and the second backside ground path 2055. The backside vias are depicted as black circles in FIG. 15B.

In this example, the second backside positive supply path 2050 and the second backside ground path 2055 allows the supply voltage and ground to be routed to the backside rails 2010, 2012, 2014, 2016, 2020, 2022, 2024, 2030, 2032, 2034, 2040, and 2042 within the variable-cell-height area 1810 independently from the rails outside of the variable-cell-height area 1810.

In this example, the backside power routing also includes a third backside positive supply path 1050b in backside metal layer BM1 and a third backside ground path 1055b in backside metal layer BM1. The third positive supply path 1050b extends in the y direction under the backside positive supply rails 1012b, 1014b, 1016b, 1018b, 1020b, and 1022b. Each of backside positive supply rails 1012b, 1014b, 1016b, 1018b, 1020b, and 1022b is coupled to the third backside positive supply path 1050b by a respective backside via (BSV0 in FIGS. 1D and 1E) disposed between the backside positive supply rail and the third backside positive supply path 1050b. The backside vias are depicted as black circles in FIG. 20B.

The third backside ground path 1055b extends in the y direction under the backside ground rails 1032b, 1034b, 1036b, 1038b, 1040b, and 1042b. Each of backside ground rails 1032b, 1034b, 1036b, 1038b, 1040b, and 1042b is coupled to the third backside ground path 1055b by a respective backside via (BSV0 in FIGS. 1D and 1E) disposed between the backside ground rail and the third backside ground path 1055b. The backside vias are depicted as black circles in FIG. 20B.

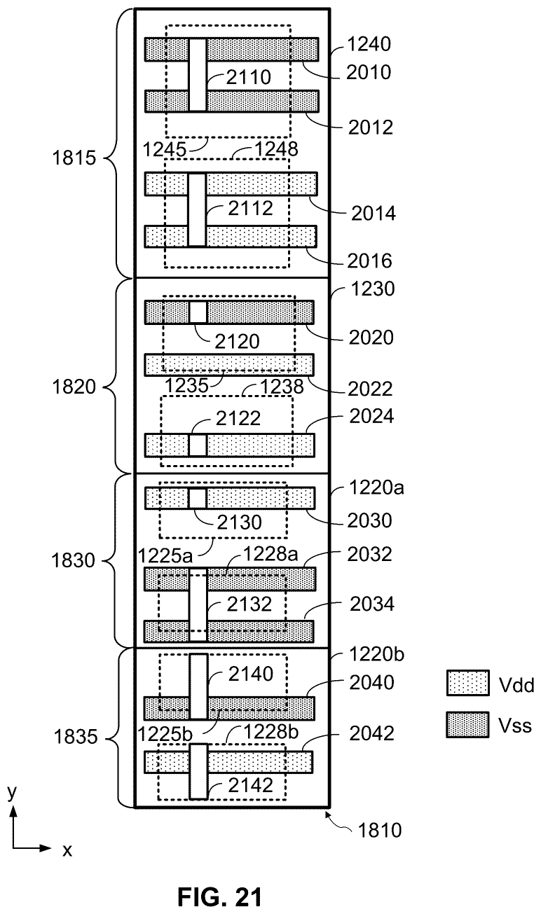

FIG. 21 shows an example of cells with varying heights placed in the rows 1815, 1820, 1830, and 1835 according to certain aspects. In this example, the cell 1240 (i.e., 2× cell) is placed in the row 1815, the cell 1230 (i.e., 1.5× cell) is placed in the row 1820, the cell 1220a (i.e., 1.25× cell) is placed in the row 1830, and the cell 1220b (i.e., 1.25× cell) is placed in the row 1835. The cells 1220a and 1220b are separate instances of the cell 1220.

In the example in FIG. 21, the first diffusion region 1245 (e.g., n-type diffusion region) of the cell 1240 is coupled to the backside ground rails 2010 and 2012 by a backside contact 2110 (e.g., BSC in FIGS. 1D and 1E) coupled between the first diffusion region 1245 and the backside ground rails 2010 and 2012. The second diffusion region 1248 (e.g., p-type diffusion region) of the cell 1240 is coupled to the backside positive supply rails 2014 and 2016 by a backside contact 2112 (e.g., BSC in FIGS. 1D and 1E) coupled between the second diffusion region 1248 and the backside positive supply rails 2014 and 2016.

In this example, the first diffusion region 1235 (e.g., n-type diffusion region) of the cell 1230 is coupled to the backside ground rail 2020 by a backside contact 2120 (e.g., BSC in FIGS. 1D and 1E) coupled between the first diffusion region 1235 and the backside ground rail 2020. The second diffusion region 1238 (e.g., p-type diffusion region) of the cell 1230 is coupled to the backside positive supply rail 2024 by a backside contact 2122 (e.g., BSC in FIGS. 1D and 1E) coupled between the second diffusion region 1238 and the backside positive supply rail 2024.

In this example, the first diffusion region 1225a (e.g., p-type diffusion region) of the cell 1220a is coupled to the backside positive supply rail 2030 by a backside contact 2130 (e.g., BSC in FIGS. 1D and 1E) coupled between the first diffusion region 1225a and the backside positive supply rail 2030. The second diffusion region 1228a (e.g., n-type diffusion region) of the cell 1230a is coupled to the backside ground rails 2032 and 2034 by a backside contact 2132 (e.g., BSC in FIGS. 1D and 1E) coupled between the second diffusion region 1228a and the backside ground rails 2032 and 2034.

In this example, the first diffusion region 1225b (e.g., n-type diffusion region) of the cell 1220b is coupled to the backside ground rail 2040 by a backside contact 2140 (e.g., BSC in FIGS. 1D and 1E) coupled between the first diffusion region 1225b and the backside ground rail 2040. The second diffusion region 1228b (e.g., n-type diffusion region) of the cell 1220b is coupled to the backside positive supply rail 2042 by a backside contact 2142 (e.g., BSC in FIGS. 1D and 1E) coupled between the second diffusion region 1228b and the backside positive supply rail 2042.

Although the backside contacts 2110, 2112, 2120, 2122, 2130, 2132, 2140, and 2142 are shown being aligned in the x direction in the example in FIG. 21, it is to be appreciated that each of the backside contacts 2110, 2112, 2120, 2122, 2130, 2132, 2140, and 2142 may be placed at another location in the x direction.

Implementation examples are described in the following numbered clauses:
1. A chip, comprising:
   first backside rails, wherein each of the first backside rails extends in a first direction, and the first backside rails are spaced apart by a uniform pitch in a second direction perpendicular to the first direction; and
   second backside rails, wherein each of the second backside rails extends in the first direction, and the second backside rails are spaced apart by a variable pitch in the second direction.
2. The chip of clause 1, wherein the first backside rails are arranged in a first column, and the second backside rails are arranged in a second column adjacent to the first column.
3. The chip of clause 1 or 2, further comprising:
   a first cell having a first height in the second direction, wherein a first boundary of the first cell overlaps a first one of the second backside rails, and a second boundary of the first cell overlaps a second one of the second backside rails; and
   a second cell having a second height in the second direction, wherein a first boundary of the second cell overlaps the second one of the second backside rails, a second boundary of the second cell overlaps a third one of the second backside rails, and the first height and the second height are different.
4. The chip of clause 3, wherein the first cell comprises:
   a first diffusion region extending in the first direction, wherein the first diffusion region is coupled to the first one of the second backside rails; and
   a second diffusion region extending in the first direction, wherein the second diffusion region is coupled to the second one of the second backside rails.
5. The chip of clause 4, further comprising:
   a first backside contact coupled between a bottom surface of the first diffusion region and the first one of the second backside rails; and
   a second backside contact coupled between a bottom surface of the second diffusion region and the second one of the second backside rails.
6. The chip of clause 4 or 5, wherein the second cell comprises:
   a third diffusion region extending in the first direction, wherein the third diffusion region is coupled to the second one of the second backside rails; and
   a fourth diffusion region extending in the first direction, wherein the fourth diffusion region is coupled to the third one of the second backside rails.
7. The chip of clause 6, wherein the first height is greater than the second height.
8. The chip of clause 7, wherein the first diffusion region is wider in the second direction than each of the third diffusion region and the fourth diffusion region.
9. The chip of any one of clauses 3 to 8, wherein each of the first height and the second height is different from the uniform pitch.
10. The chip of clause 9, wherein the first height is greater than the uniform pitch and the second height is less than the uniform pitch.
11. The chip of any one of clauses 3 to 10, wherein the first one of the second backside rails comprises a first backside positive supply rail, the second one of the second backside rails comprises a backside ground rail, and the third one of the second backside rails comprises a second backside positive supply rail.
12. The chip of any one of clauses 3 to 10, wherein the first one of the second backside rails comprises a first backside ground rail, the second one of the second backside rails comprises a backside positive supply rail, and the third one of the second backside rails comprises a second backside ground rail.
13. The chip of any one of clauses 3 to 12, further comprising a third cell having a third height in the second direction, wherein a first boundary of the third cell overlaps the third one of the second backside rails, and a second boundary of the third cell overlaps a fourth one of the second backside rails, wherein the first height, the second height, and the third height are different.
14. The chip of clause 13, wherein each of the first height, the second height, and the third height is different from the uniform pitch.
15. The chip of clause 14, wherein one of the first height, the second height, and the third height is greater than the uniform pitch, and another one of first height, the second height, and the third height is less than the uniform pitch.
16. A chip, comprising:
   first backside rails extending in a first direction;
   first cells within a first area of the chip, wherein the first cells have a uniform height in a second direction perpendicular to the first direction, and the first backside rails extend under the first cells;
   second backside rails extending in the first direction; and
   second cells within a second area of the chip, wherein the second cells have a variable height in the second direction, and the second backside rails extend under the second cells.
17. The chip of clause 16, wherein the first backside rails are aligned with the second backside rails in the second direction.
18. The chip of clause 17, wherein a first one of the first backside rails comprises a positive supply rail, and a first one of the second backside rails comprises a ground rail aligned with the positive supply rail in the second direction.
19. The chip of anyone of clauses 16 to 18, wherein the first cells are arranged in a first column, and the second cells are arranged in a second column.
20. The chip of any one of clauses 16 to 19, wherein a first one of the second cells has a height that is greater than the uniform height, and a second one of the second cells has a height that is less than the uniform height.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
first backside rails, wherein each of the first backside rails extends in a first direction, and the first backside rails are spaced apart by a uniform pitch in a second direction perpendicular to the first direction; and
second backside rails, wherein each of the second backside rails extends in the first direction, and the second backside rails are spaced apart by a variable pitch in the second direction.

2. The chip of claim 1, wherein the first backside rails are arranged in a first column, and the second backside rails are arranged in a second column adjacent to the first column.

3. The chip of claim 1, further comprising:
a first cell having a first height in the second direction, wherein a first boundary of the first cell overlaps a first one of the second backside rails, and a second boundary of the first cell overlaps a second one of the second backside rails; and
a second cell having a second height in the second direction, wherein a first boundary of the second cell overlaps the second one of the second backside rails, a second boundary of the second cell overlaps a third one of the second backside rails, and the first height and the second height are different.

4. The chip of claim 3, wherein the first cell comprises:
a first diffusion region extending in the first direction, wherein the first diffusion region is coupled to the first one of the second backside rails; and
a second diffusion region extending in the first direction, wherein the second diffusion region is coupled to the second one of the second backside rails.

5. The chip of claim 4, further comprising:
a first backside contact coupled between a bottom surface of the first diffusion region and the first one of the second backside rails; and
a second backside contact coupled between a bottom surface of the second diffusion region and the second one of the second backside rails.

6. The chip of 4, wherein the second cell comprises:
a third diffusion region extending in the first direction, wherein the third diffusion region is coupled to the second one of the second backside rails; and
a fourth diffusion region extending in the first direction, wherein the fourth diffusion region is coupled to the third one of the second backside rails.

7. The chip of claim 6, wherein the first height is greater than the second height.

8. The chip of claim 7, wherein the first diffusion region is wider in the second direction than each of the third diffusion region and the fourth diffusion region.

9. The chip of claim 3, wherein each of the first height and the second height is different from the uniform pitch.

10. The chip of claim 9, wherein the first height is greater than the uniform pitch and the second height is less than the uniform pitch.

11. The chip of claim 3, wherein the first one of the second backside rails comprises a first backside positive supply rail, the second one of the second backside rails comprises a backside ground rail, and the third one of the second backside rails comprises a second backside positive supply rail.

12. The chip of claim 3, wherein the first one of the second backside rails comprises a first backside ground rail, the second one of the second backside rails comprises a backside positive supply rail, and the third one of the second backside rails comprises a second backside ground rail.

13. The chip of claim 3, further comprising a third cell having a third height in the second direction, wherein a first boundary of the third cell overlaps the third one of the second backside rails, and a second boundary of the third cell overlaps a fourth one of the second backside rails, wherein the first height, the second height, and the third height are different.

14. The chip of claim 13, wherein each of the first height, the second height, and the third height is different from the uniform pitch.

15. The chip of claim 14, wherein one of the first height, the second height, and the third height is greater than the uniform pitch, and another one of first height, the second height, and the third height is less than the uniform pitch.

16. A chip, comprising:
first backside rails extending in a first direction;
first cells within a first area of the chip, wherein the first cells have a uniform height in a second direction perpendicular to the first direction, and the first backside rails extend under the first cells;
second backside rails extending in the first direction; and
second cells within a second area of the chip, wherein the second cells have a variable height in the second direction, and the second backside rails extend under the second cells.

17. The chip of claim 16, wherein the first backside rails are aligned with the second backside rails in the second direction.

18. The chip of claim 17, wherein a first one of the first backside rails comprises a positive supply rail, and a first one of the second backside rails comprises a ground rail aligned with the positive supply rail in the second direction.

19. The chip of claim 16, wherein the first cells are arranged in a first column, and the second cells are arranged in a second column.

20. The chip of claim 16, wherein a first one of the second cells has a height that is greater than the uniform height, and a second one of the second cells has a height that is less than the uniform height.
